(19) United States
(12) Patent Application Publication
(10) Pub. No.: US 2026/0040744 A1
(43) Pub. Date: Feb. 5, 2026

(54) DISPLAY DEVICE AND METHOD OF MANUFACTURING THE SAME

(71) Applicant: LG Display Co., Ltd., Seoul (KR)

(72) Inventors: Jae Kwang LEE, Paju-si (KR); Dae Han WON, Paju-si (KR); Hae Sung LEE, Paju-si (KR)

(73) Assignee: LG Display Co., Ltd., Seoul (KR)

(21) Appl. No.: 19/254,893

(22) Filed: Jun. 30, 2025

(30) Foreign Application Priority Data
Jul. 31, 2024 (KR) 10-2024-0102125

(51) Int. Cl. H10H 29/49; H10H 29/01; H10H 29/41

(52) U.S. Cl. CPC H10H 29/49; H10H 29/012; H10H 29/41

(57) ABSTRACT

The present disclosure provides a display device and a method of manufacturing a display device. A display device according to one embodiment of the present specification may include a substrate including a display area and a non-display area around the display area, a signal line located in the display area, a test pad located in the non-display area, and a connection line located in the non-display area and configured to electrically connect the test pad and the signal line. The test pad may include a bank, a first layer, which is the connection line, disposed on the bank, a photoresist layer disposed on the first layer and including a pattern area, and a second layer disposed on the photoresist layer. The pattern area may have a positive taper cross-section, and the first layer and the second layer are in contact with each other in the pattern area.

### CROSS-REFERENCE TO RELATED APPLICATION

This application claims priority to and the benefit of Korean Patent Application No. 10-2024-0102125, filed on Jul. 31, 2024, the disclosure of which is incorporated herein by reference in its entirety.

### BACKGROUND

### 1. Field of the Disclosure

The present specification relates to a display device and a method of manufacturing the same.

### 2. Discussion of Related Art

Display devices are being applied to various electronic devices such as TVs, mobile phones, laptops, and tablets.

Display devices include organic light-emitting display (OLED) devices, which are self-emissive, liquid crystal display (LCD) devices, which require a separate light source, and the like.

In recent years, display devices including light-emitting diodes (LEDs) have been gaining attention as next-generation display devices. Since LEDs are formed of inorganic materials rather than organic materials, the display devices including LEDs have a fast lighting speed and high luminous efficacy, and can display high-brightness images compared to liquid crystal display devices and organic light-emitting display devices.

### SUMMARY

During the deposition process of materials for layers used in display device manufacturing, electrostatic discharge (ESD) may occur.

Embodiments of the present specification are directed to providing a display device capable of reducing ESD and a method of manufacturing the same.

Objectives according to embodiments of the present specification are not limited to the above-described objectives, and other objectives that are not described herein will be apparently understood by those skilled in the art from the following description.

A display device according to an example embodiment of the present specification includes a substrate including a display area and a non-display area around the display area, a signal line located in the display area, a test pad located in the non-display area, and a connection line located in the non-display area and configured to electrically connect the test pad and the signal line. The test pad may include a bank, a first layer, which is the connection line, disposed on the bank, a photoresist layer disposed on the first layer and including a pattern area, and a second layer disposed on the photoresist layer. The pattern area may have a positive taper cross-section, and the first layer and the second layer may be in contact with each other in the pattern area.

In another aspect, a method of manufacturing a display device according to an example embodiment of the present specification includes forming a bank on a substrate, forming a first layer, which is a connection line connected to a test pad, on the bank, forming a photoresist layer on the first layer, forming a pattern area in the photoresist layer through exposure, and forming a second layer on the photoresist layer in which the pattern area is formed. The pattern area may have a positive taper cross-section, and the first layer and the second layer may be in contact with each other in the pattern area.

Specific details according to various examples of the present specification are included in the description and drawings below. It is to be understood that both the foregoing general description and the following detailed description are by way of example and explanatory and are intended to provide further explanation of the inventive concepts as claimed.

### BRIEF DESCRIPTION OF THE DRAWINGS

The accompanying drawings, which are included to provide a further understanding of the present disclosure and are incorporated in and constitute a part of this application, illustrate example embodiments of the present disclosure and together with the description serve to explain various principles of the disclosure. In the drawings:

FIG. 1 is an exploded perspective view of a display device according to an example embodiment of the present specification;

FIG. 2 is a plan view of the display device according to an example embodiment of the present specification;

FIG. 3 is an enlarged view of the display device according to an example embodiment of the present specification;

FIG. 4 is a diagram illustrating a circuit structure according to an example embodiment of the present specification;

FIG. 5 is a plan view of a display device according to an example embodiment of the present specification;

FIG. 6 is a plan view of the display device according to an example embodiment of the present specification;

FIG. 7 is a plan view of the display device according to an example embodiment of the present specification;

FIG. 8 is a cross-sectional view of the display device according to an example embodiment of the present specification;

FIG. 9 is a cross-sectional view of the display device according to an example embodiment of the present specification;

FIGS. 10 to 13 are views illustrating devices to which the display device according to example embodiments of the present specification can be applied;

FIG. 14 is a plan view of a display panel according to an example embodiment of the present specification;

FIG. 15 is a cross-sectional view of the display panel according to an example embodiment of the present specification;

FIG. 16 is an enlarged cross-sectional view of region 1 of FIG. 15;

FIG. 17 is a view illustrating an example masking pattern constituting a test pad of FIG. 16;

FIG. 18 is an enlarged plan view of region 1 of FIG. 15; and

FIG. 19 is a view illustrating an implementation of the test pad according to an example embodiment of the present specification.

### DETAILED DESCRIPTION

Advantages and features of the present disclosure and a method of achieving the same should become clear with various example embodiments described in detail below with reference to the accompanying drawings. However, the present disclosure is not limited to the embodiments described below and may be implemented in various different forms. The following example embodiments are merely provided to allow those skilled in the art to completely understand the scope of the present disclosure.

The shapes, dimensions, ratios, angles, numbers, and the like disclosed in the drawings for describing the embodiments of the present specification are merely illustrative and are not limited to matters shown in the present specification. Like reference numerals refer to like elements throughout the specification. Further, in describing the present specification, detailed descriptions of well-known technologies may be omitted where they may unnecessarily obscure the features of the present specification. Terms such as “including,” “having,” and “composed of” used herein are intended to allow other elements to be added unless the terms are used with a more limiting term like “only.” Any references to the singular may include the plural, and vice versa, unless expressly stated otherwise.

Components are interpreted as including an ordinary error range even if no such margin is explicitly stated.

In the case of a description of a positional relationship, for example, where a positional relationship between two portions is described with the terms “on,” “above,” “under,” “next to,” or the like, one or more portions may be interposed therebetween unless a more limiting term, for example, “right”, “directly”, or “near” is used in the expression.

For the description of a temporal relationship, where a temporal relationship is described as “after,” “subsequently to,” “next,” “before,” and the like, a non-consecutive case may be included unless a more limiting term like “immediately” or “directly” is used in the expression.

Although the terms “first,” “second,” and the like may be used herein to describe various components, the components are not limited by the terms. These terms are used only to refer to one component separately from another. Therefore, a first component described below may be a second component, and vice versa, within the technical scope of the present specification.

Terms such as first, second, A, B, (a), (b), or the like may be used herein when describing components of the present specification. Such terms are used only to refer to a component separately from another component, but do not limit the nature, sequence, order, number, or the like of components.

It is to be understood that, where a component is described as being “connected,” “coupled,” “linked,” or “attached” to another component, the component may be directly connected, coupled, linked, or attached to the other component, but, unless specifically stated otherwise, still another component may be interposed between the two components so that they are indirectly connected, coupled, linked, or attached.

It is also to be understood that, where a component or layer is described as being “in contact with” or “overlapping” another component or layer, the component or layer may be in direct contact with or directly overlapping the other component or layer, but, unless specifically stated otherwise, still another component or layer may be interposed between the two components or layers so that they are in indirect contact with or indirectly overlapping each other.

The term “at least one” should be understood as including any and all combinations of one or more of the associated listed components. For example, the meaning of “at least one of a first component, a second component, and a third component” denotes any combination of two or more of the first component, the second component, and the third component as well as any of the first component, the second component, or the third component.

The terms “first direction,” “second direction,” “third direction,” “X-axis direction,” “Y-axis direction,” and “Z-axis direction” should not be interpreted as referring only to geometrical relationships that are perpendicular to each other, but may indicate a broader range of directions within the functional scope of the configuration described in the present specification.

Features of various embodiments of the present specification may be partially or fully coupled or combined with each other, and technically, various types of interconnections and driving are possible. The embodiments of the present specification may be implemented independently of each other or may be implemented together in an interconnected relationship.

Hereinafter, various example embodiments of the present disclosure will be described in detail with reference to the accompanying drawings.

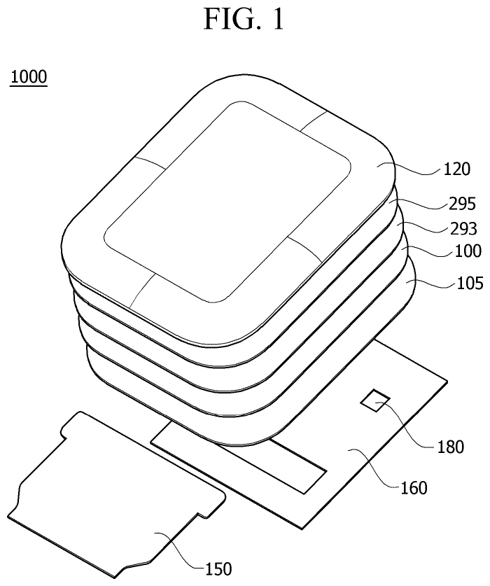

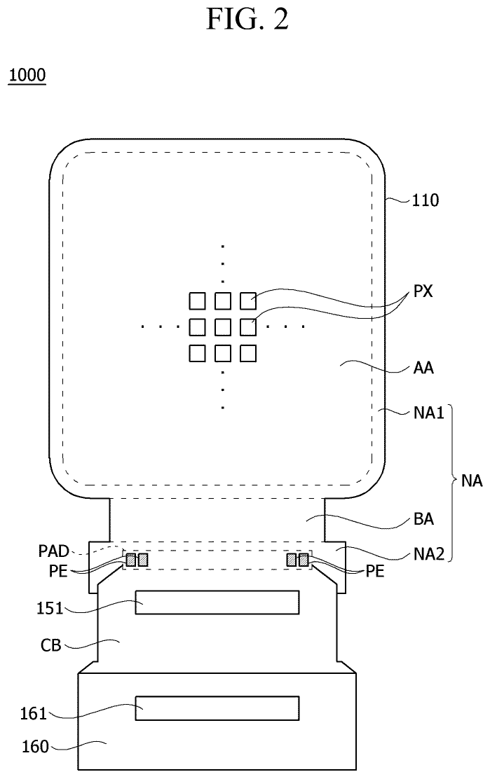

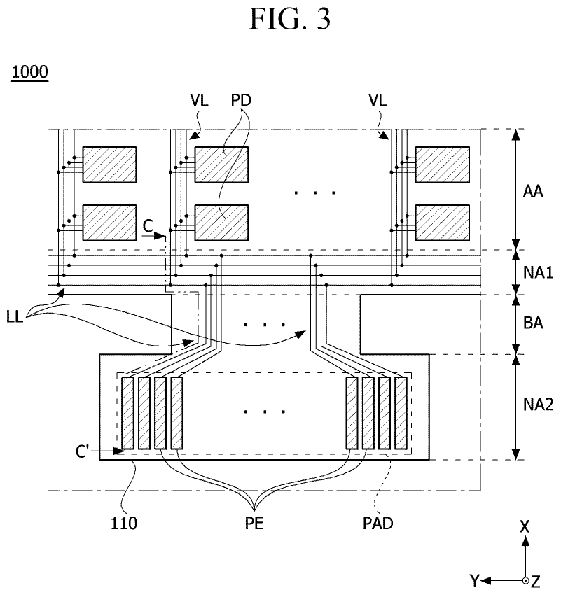

FIG. 1 is a perspective view illustrating a display device according to an example embodiment of the present specification. FIG. 2 is a plan view of the display device according to an example embodiment of the present specification. FIG. 3 is an enlarged view of the display device according to an example embodiment of the present specification.

As shown in FIGS. 1 to 3, a display device 1000 according to an embodiment of the present specification may include a display panel 100, a polarizing layer 293, a second adhesive layer 295, a cover member 120, a support substrate 105, a flexible circuit board CB, and a printed circuit board 160.

For example, the display device 1000 may include a substrate 110. The substrate 110 may be a member that supports other components of the display device 1000. The substrate 110 may be formed of an insulating material. For example, the substrate 110 may be formed of glass, resin, or the like. In addition, the substrate 110 may be formed of a material that has flexibility. For example, the substrate 110 may be formed of a plastic material having flexibility, such as polyimide (PI). However, the embodiments of the present specification are not limited thereto.

The display panel 100 may implement information, videos, and/or images provided to a user. For example, the display panel 100 may include a display area AA and a non-display area NA. For example, the substrate 110 may include the display area AA and the non-display area NA. The display area AA and the non-display area NA are not limited to the substrate 110 but may be provided throughout the entire display device 1000.

The display area AA may be an area in which an image is displayed. The display area AA may include a plurality of pixels PX. Each of the plurality of pixels PX may be composed of a plurality of sub-pixels. A plurality of light-emitting elements may be disposed in each of the plurality of sub-pixels. The plurality of light-emitting elements may be configured differently depending on the type of the display device 1000. For example, when the display device 1000 is an inorganic light-emitting display device, the light-emitting element may be a light-emitting diode (LED), a micro light-emitting diode (micro LED), or a mini light-emitting diode (mini LED), but the embodiments of the present specification are not limited thereto.

The non-display area NA may be an area in which an image is not displayed. Various lines, circuits, and the like for driving the plurality of pixels PX of the display area AA may be disposed in the non-display area NA. For example, in the non-display area NA, various lines and driving circuits may be mounted, and a pad part PAD to which an integrated circuit, a printed circuit, or the like is connected may be disposed, but the embodiments of the present specification are not limited thereto.

For example, the driving circuits may be data driving circuits and/or gate driving circuits, but the embodiments of the present specification are not limited thereto. Lines through which control signals for controlling the driving circuits are supplied may be disposed on the display panel. For example, the control signals may include various timing signals such as clock signals, input data enable signals, and synchronization signals, but the embodiments of the present specification are not limited thereto. The control signals may be received through the pad part PAD. For example, link lines LL for transmitting signals may be disposed in the non-display area NA. For example, driving components such as the flexible circuit board CB and the printed circuit board 160 may be connected to the pad part PAD.

According to the present specification, the non-display area NA may include a first non-display area NA1, a bending area BA, and a second non-display area NA2. For example, the first non-display area NA1 may be an area surrounding at least a portion of the display area AA. The bending area BA may be an area extending from at least one of a plurality of sides of the first non-display area NA1, and may be a bendable area. The second non-display area NA2 may be an area extending from the bending area BA, and the pad part PAD may be disposed therein. For example, the bending area BA may be in a bent state, and the remaining area of the substrate 110, excluding the bending area BA, may be in a flat state. As the bending area BA is bent, the second non-display area NA2 may be located on a rear surface of the display area AA. However, the embodiments of the present specification are not limited thereto.

The display area AA of the substrate 110 or the display device 1000 may be configured in various shapes depending on the design of the display device 1000. For example, the display area AA may be configured in a rectangular shape with four rounded corners, but the embodiments of the present specification are not limited thereto. For another example, the display area AA may be configured in a rectangular shape with four right-angled corners, a circular shape, or the like, but the embodiments of the present specification are not limited thereto.

According to the present specification, a width of the second non-display area NA2, in which a plurality of pad electrodes PE are disposed, may be greater than a width of the bending area BA, in which only the plurality of link lines LL are disposed. In addition, a width of the display area AA in which the plurality of sub-pixels are disposed may be greater than the width of the bending area BA in which only the plurality of link lines LL are disposed. In the drawings, the width of the bending area BA is illustrated as being less than that of each of the other areas of the substrate 110, but the shape of the substrate 110 including the bending area BA is an example, and the embodiments of the present specification are not limited thereto.

As shown in FIG. 3, a plurality of pixel driving circuits PD may be disposed in the display area AA. The plurality of pixel driving circuits PD may be circuits for driving the light-emitting elements of the plurality of sub-pixels. Each of the plurality of pixel driving circuits PD includes a plurality of transistors including driving transistors, a storage capacitor, and the like, and the pixel driving circuits PD may supply control signals, power, and driving current to the light-emitting elements of the plurality of sub-pixels, thereby controlling the light-emission operations of the plurality of light-emitting elements. For example, the pixel driving circuit PD may include power lines and signal lines for controlling an on/off state and/or a light-emission time of the light-emitting element. For example, the plurality of pixel driving circuits PD may be driving drivers fabricated using a metal-oxide-silicon field-effect transistor (MOSFET) manufacturing process on a semiconductor substrate, but the embodiments of the present specification are not limited thereto. The driving drivers include the plurality of pixel driving circuits PD, and may drive the plurality of sub-pixels.

As shown in FIGS. 1 and 2 together, the flexible circuit board CB and the printed circuit board 160 may be disposed below the display panel 100.

The flexible circuit board CB and the printed circuit board 160 may be disposed at at least one side edge of the display panel 100, but the embodiments of the present specification are not limited thereto. One side of the flexible circuit board CB may be attached to the display panel 100, and the other side thereof may be attached to the printed circuit board 160, but the embodiments of the present specification are not limited thereto. The flexible circuit board CB may be a flexible film, but the embodiments of the present specification are not limited thereto.

The pad part PAD including the plurality of pad electrodes PE may be disposed in the second non-display area NA2. The driving components, including one or more flexible circuit boards (or flexible films) CB and the printed circuit board 160, may be attached or bonded to the pad part PAD. The plurality of pad electrodes PE of the pad part PAD are electrically connected to one or more flexible circuit boards (or flexible films) CB and may transmit various signals (or power) output from the printed circuit board 160 and the flexible circuit boards (or flexible films) CB to the plurality of pixel driving circuits PD in the display area AA.

The flexible circuit board (or flexible film) CB may be a film in which various components are disposed on a base film having flexibility. For example, a driving integrated circuit (IC) such as a gate driver IC or a data driver IC may be disposed on the flexible circuit board (or flexible film) CB, but the embodiments of the present specification are not limited thereto. The driving IC may be a component that processes data and driving signals for displaying images. The driving IC may be disposed using methods such as chip on glass (COG), chip on film (COF), or tape carrier package (TCP) depending on a mounting method, but the embodiments of the present specification are not limited thereto. The flexible circuit board (or flexible film) CB may be attached or bonded onto the plurality of pad electrodes PE through a conductive adhesive layer, but the embodiments of the present specification are not limited thereto. For example, the flexible circuit board CB may include a control circuit such as a timing controller (T-CON) 151.

The printed circuit board 160 may be a component that is electrically connected to one or more flexible circuit boards (or flexible films) CB and supplies signals to the driving IC. The printed circuit board 160 may be disposed on one side of the flexible circuit board (or flexible film) CB, and may be electrically connected to the flexible circuit board (or flexible film) CB.

Various components for supplying various signals to the driving IC may be disposed on the printed circuit board 160. For example, various components such as a timing controller, a power supply part, a memory, or a processor may be disposed on the printed circuit board 160. For example, the printed circuit board 160 may include a power management integrated circuit (PMIC) 161, but the embodiments of the present specification are not limited thereto.

The printed circuit board 160 may include at least one hole 180, but the embodiments of the present specification are not limited thereto. An internal component configured to detect ambient light or temperature, which may be provided to a plurality of sensors, may be disposed in an area corresponding to at least one hole 180. For example, the internal component may include an ambient light sensor (ALS), a temperature sensor, or the like, but the embodiments of the present specification are not limited thereto. For example, the hole 180 may be a through hole or the like, but the embodiments of the present specification are not limited thereto.

As shown in FIG. 1, the polarizing layer 293 may be disposed on the display panel 100. The polarizing layer 293 may prevent or reduce the light generated from an external light source from entering the display panel 100 and affecting the light-emitting elements or the like.

The cover member 120 may be disposed on the polarizing layer 293. The cover member 120 may be a member for protecting the display panel 100. The second adhesive layer 295 may be disposed between the polarizing layer 293 and the cover member 120. The cover member 120 may be attached to the display panel 100 by the second adhesive layer 295. The second adhesive layer 295 may include an optically clear adhesive (OCA), an optically clear resin (OCR), a pressure-sensitive adhesive (PSA), or the like, but the embodiments of the present specification are not limited thereto.

The support substrate 105 may be disposed between the display panel 100 and the printed circuit board 160. The support substrate 105 may reinforce the rigidity of the display panel 100. The support substrate 105 may be a back plate, but the embodiments of the present specification are not limited thereto.

As shown in FIGS. 1 to 3, a plurality of link lines LL may be disposed in the non-display area NA. The plurality of link lines LL may be lines that transmit various signals supplied from one or more flexible circuit boards (or flexible films) CB and the printed circuit board 160 to the display area AA. The plurality of link lines LL may extend from the plurality of pad electrodes PE in the second non-display area NA2 toward the bending area BA and the first non-display area NA1 and may be electrically connected to a plurality of driving lines VL in the display area AA. The plurality of pixel driving circuits PD may be driven by receiving signals from one or more flexible circuit boards (or flexible films) CB and the printed circuit board 160 through the driving lines VL in the display area AA and the link lines LL in the non-display area NA.

For example, the plurality of driving lines VL, along with the plurality of link lines LL, may serve as lines for transmitting signals output from the flexible circuit board (or flexible film) CB and the printed circuit board 160 to the plurality of pixel driving circuits PD. The plurality of driving lines VL may be disposed in the display area AA and electrically connected to the plurality of pixel driving circuits PD, respectively. The plurality of driving lines VL may extend from the display area AA toward the non-display area NA to be electrically connected to the plurality of link lines LL. Accordingly, the signals output from the flexible circuit board (or flexible film) CB and the printed circuit board 160 may be transmitted to each of the plurality of pixel driving circuits PD through the plurality of link lines LL and the plurality of driving lines VL.

As the bending area BA is bent, some of the plurality of link lines LL may also be bent. Stress may be concentrated on a portion of the bent link lines LL, and as a result, cracks may occur in the link lines LL. Accordingly, the plurality of link lines LL may be formed of a conductive material with excellent flexibility to reduce cracks during the bending of the bending area BA. For example, the plurality of link lines LL may be formed of a conductive material with excellent flexibility such as gold (Au), silver (Ag), or aluminum (Al), but the embodiments of the present specification are not limited thereto. In addition, the plurality of link lines LL may be formed of one of various conductive materials used in the display area AA. For example, the plurality of link lines LL may be formed of molybdenum (Mo), chromium (Cr), titanium (Ti), nickel (Ni), neodymium (Nd), copper (Cu), an alloy of silver (Ag) and magnesium (Mg), or alloys thereof, but the embodiments of the present specification are not limited thereto. The plurality of link lines LL may be configured in a multilayer structure including various conductive materials. For example, the plurality of link lines LL may be configured in a triple-layer structure of titanium (Ti)/aluminum (Al)/titanium (Ti), but the embodiments of the present specification are not limited thereto.

The plurality of link lines LL may be configured in various shapes to reduce stress. At least some of the plurality of link lines LL disposed in the bending area BA may extend in the same direction as an extension direction of the bending area BA, or extend in a direction different from the extension direction of the bending area BA to reduce stress. For example, when the bending area BA extends in one direction from the first non-display area NA1 toward the second non-display area NA2, at least some of the link lines LL disposed in the bending area BA may extend in a direction oblique to the one direction along which the bending area BA extends. For another example, at least some of the plurality of link lines LL may be configured in various pattern shapes. For example, at least some of the plurality of link lines LL disposed in the bending area BA may have a conductive pattern repetitively disposed in at least one shape among a diamond shape, a rhombus shape, a trapezoidal wave shape, a triangular wave shape, a sawtooth wave shape, a sine wave shape, a circular shape, and an omega (Ω) shape, but the embodiments of the present specification are not limited thereto. Accordingly, to minimize or reduce the stress concentrated on the plurality of link lines LL and the resulting cracks, the plurality of link lines LL may be formed in various shapes including the above-described shapes, but the embodiments of the present specification are not limited thereto.

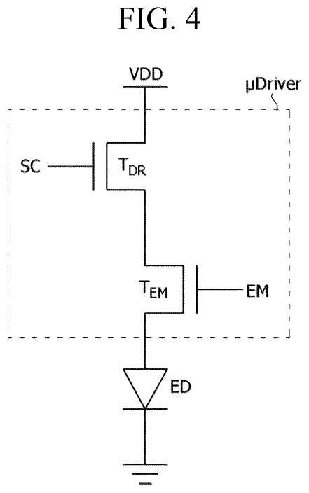

FIG. 4 is a diagram illustrating a circuit structure according to an example embodiment of the present specification.

In FIG. 4, an example is illustrated in which one light-emitting element ED is connected to a micro driver μDriver, but the present specification is not limited thereto. For example, eight light-emitting elements ED may be connected to one micro driver μDriver. For another example, 16 light-emitting elements ED may be connected to one micro driver μDriver, or 32 light-emitting elements ED or 64 light-emitting elements ED may be simultaneously connected to one micro driver μDriver. The light-emitting element ED may be a micro light-emitting element (μLED).

The micro driver μDriver may include a driving transistor T_{DR} and a light-emitting transistor T_{EM}, but the embodiments of the present specification are not limited thereto.

For example, the driving transistor T_{DR} has a first electrode to which a high-potential power voltage VDD may be applied, a second electrode to which a first electrode of the light-emitting transistor T_{EM} may be connected, and a gate electrode to which a scan signal SC may be applied. The scan signal SC applied to the gate electrode of the driving transistor T_{DR} may be direct current (DC) power, and a fixed reference voltage Vref may be applied for each frame, but the embodiments of the present specification are not limited thereto.

The light-emitting transistor T_{EM} has the first electrode to which the second electrode of the driving transistor T_{DR} may be connected, a second electrode to which the light-emitting element ED may be connected, and a gate electrode to which a light-emission signal EM may be applied. The light-emission signal EM applied to the gate electrode of the light-emitting transistor T_{EM} may be a pulse width modulation (PWM) signal that varies for each frame, but the embodiments of the present specification are not limited thereto.

A first electrode of the light-emitting element ED may be connected to the second electrode of the light-emitting transistor T_{EM}, and a second electrode thereof may be connected to the ground. For example, the first electrode may be an anode, and the second electrode may be a cathode, but the embodiments of the present specification are not limited thereto.

The driving transistor T_{DR} and the light-emitting transistor T_{EM} may each be an n-type transistor or a p-type transistor.

In the micro driver μDriver, the driving transistor T_{DR} may be turned on by the scan signal SC applied from a timing controller (T-CON), and the light-emitting transistor T_{EM} may be turned on by the light-emission signal EM. As a result, a driving current may be applied to the light-emitting element ED via the driving transistor T_{DR} and the light-emitting transistor T_{EM} by the high-potential power voltage VDD applied to the first electrode of the driving transistor T_{DR}, thereby enabling the light-emitting element ED to emit light.

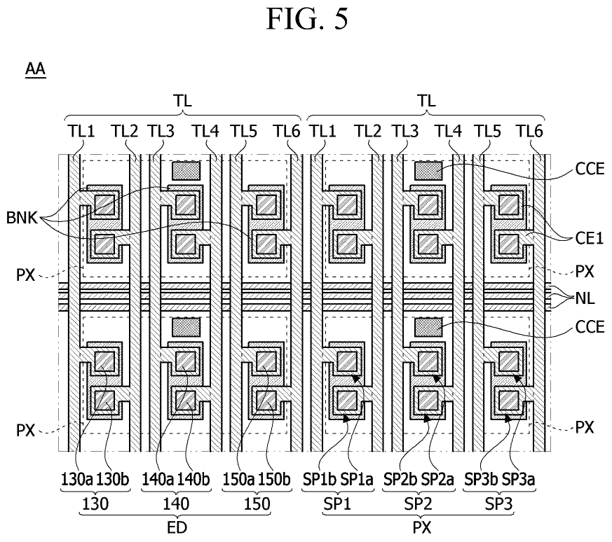

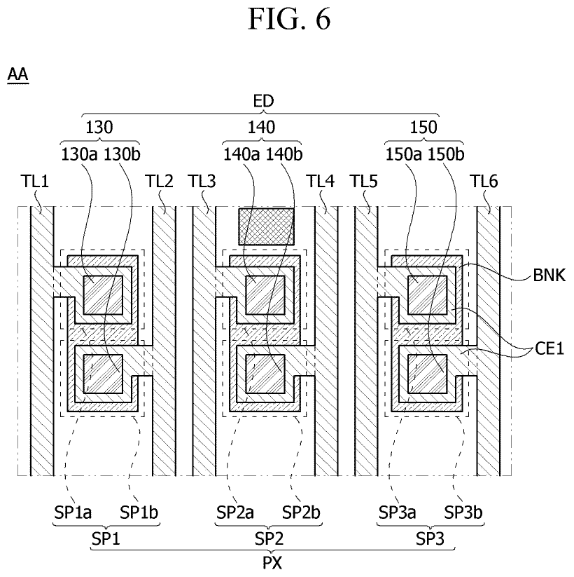

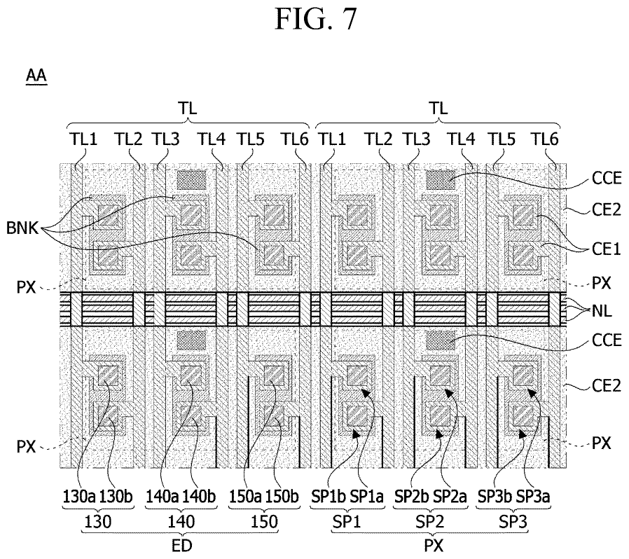

FIGS. 5 to 7 are plan views of a display device according to an example embodiment of the present specification. For example, FIG. 5 is an enlarged plan view of a display area including a plurality of pixels. For example, FIG. 6 is an enlarged plan view of the display area including one pixel. For example, FIG. 7 is an enlarged plan view of the display area including the plurality of pixels. FIGS. 5 and 6 illustrate only a plurality of signal lines TL, a plurality of communication lines NL, a plurality of first electrodes CE1, a plurality of banks BNK, and a plurality of light-emitting elements ED, but the embodiments of the present specification are not limited thereto. FIG. 7 is an enlarged plan view in which a plurality of second electrodes CE2 are additionally disposed in FIG. 5.

As shown in FIGS. 5 and 6, a plurality of pixels PX, each composed of a plurality of sub-pixels, may be disposed in the display area AA. Each of the plurality of sub-pixels includes a light-emitting element ED and may emit light independently. The plurality of sub-pixels may be disposed in a matrix form forming a plurality of rows and a plurality of columns, but the embodiments of the present specification are not limited thereto.

The plurality of sub-pixels may include a first sub-pixel SP1, a second sub-pixel SP2, and a third sub-pixel SP3. For example, one of the first sub-pixel SP1, the second sub-pixel SP2, and the third sub-pixel SP3 may be a red sub-pixel, another one thereof may be a green sub-pixel, and the remaining one thereof may be a blue sub-pixel. The types of the plurality of sub-pixels are examples, and the embodiments of the present specification are not limited thereto.

Each of the plurality of pixels PX may include one or more first sub-pixels SP1, one or more second sub-pixels SP2, and one or more third sub-pixels SP3. For example, one pixel PX may include a pair of first sub-pixels SP1, a pair of second sub-pixels SP2, and a pair of third sub-pixels SP3. The pair of first sub-pixels SP1 may be composed of a 1-1 sub-pixel SP1a and a 1-2 sub-pixel SP1b. The pair of second sub-pixels SP2 may be composed of a 2-1 sub-pixel SP2a and a 2-2 sub-pixel SP2b. The pair of third sub-pixels SP3 may be composed of a 3-1 sub-pixel SP3a and a 3-2 sub-pixel SP3b. For example, one pixel PX may include the 1-1 sub-pixel SP1a and the 1-2 sub-pixel SP1b, the 2-1 sub-pixel SP2a and the 2-2 sub-pixel SP2b, and the 3-1 sub-pixel SP3a and the 3-2 sub-pixel SP3b, but the embodiments of the present specification are not limited thereto.

The plurality of sub-pixels constituting one pixel PX may be arranged in various ways. For example, in one pixel PX, the pair of first sub-pixels SP1 may be disposed in the same column, the pair of second sub-pixels SP2 may be disposed in the same column, and the pair of third sub-pixels SP3 may be disposed in the same column. The first sub-pixel SP1, the second sub-pixel SP2, and the third sub-pixel SP3 may be disposed in the same row. The number and arrangement of the plurality of sub-pixels constituting one pixel PX are examples, and the embodiments of the present specification are not limited thereto.

The plurality of signal lines TL may be disposed in areas between the plurality of sub-pixels. The plurality of signal lines TL may extend in a column direction between the plurality of sub-pixels. The plurality of signal lines TL may be lines that transmit an anode voltage output from the pixel driving circuit PD to the plurality of sub-pixels. For example, the plurality of signal lines TL may be electrically connected to the plurality of pixel driving circuits PD and the first electrodes CE1 of the plurality of sub-pixels. The anode voltage output from the pixel driving circuit PD may be transmitted to the first electrodes CE1 of the plurality of sub-pixels through the plurality of signal lines TL. For example, the first electrode CE1 may be an electrode that is electrically connected to an anode 134 of the light-emitting element ED. Thus, the anode voltage transmitted through the signal line TL may be transmitted to the anode 134 of the light-emitting element ED through the first electrode CE1.

Accordingly, the structure of the display device 1000 may be simplified by using the pixel driving circuit PD, in which a plurality of pixel circuits are integrated, instead of forming a plurality of transistors and a storage capacitor in each of the plurality of sub-pixels. In addition, as the circuits disposed in each of the plurality of sub-pixels are integrated into one pixel driving circuit PD, high-efficiency and low-power operation may be enabled.

The plurality of signal lines TL may include a first signal line TL1, a second signal line TL2, a third signal line TL3, a fourth signal line TL4, a fifth signal line TL5, and a sixth signal line TL6. The first signal line TL1 and the second signal line TL2 may be electrically connected to the pair of first sub-pixels SP1, respectively. The third signal line TL3 and the fourth signal line TL4 may be electrically connected to the pair of second sub-pixels SP2, respectively. The fifth signal line TL5 and the sixth signal line TL6 may be electrically connected to the pair of third sub-pixels SP3, respectively.

The first signal line TL1 may be disposed on one side of the pair of first sub-pixels SP1, and the second signal line TL2 may be disposed on the other side of the pair of first sub-pixels SP1. The first signal line TL1 may be electrically connected to the first electrode CE1 of one of the pair of first sub-pixels SP1, for example, the 1-1 sub-pixel SP1a. The second signal line TL2 may be electrically connected to the first electrode CE1 of the other of the pair of first sub-pixels SP1, for example, the 1-2 sub-pixel SP1b.

The third signal line TL3 may be disposed on one side of the pair of second sub-pixels SP2, and the fourth signal line TL4 may be disposed on the other side of the pair of second sub-pixels SP2. For example, the third signal line TL3 may be disposed adjacent to the second signal line TL2. The third signal line TL3 may be electrically connected to the first electrode CE1 of one of the pair of second sub-pixels SP2, for example, the 2-1 sub-pixel SP2a. The fourth signal line TLA may be electrically connected to the first electrode CE1 of the other of the pair of second sub-pixels SP2, for example, the 2-2 sub-pixel SP2b.

The fifth signal line TL5 may be disposed on one side of the pair of third sub-pixels SP3, and the sixth signal line TL6 may be disposed on the other side of the pair of third sub-pixels SP3. For example, the fifth signal line TL5 may be disposed adjacent to the fourth signal line TL4. The sixth signal line TL6 may be disposed adjacent to the first signal line TL1 connected to the neighboring pixel PX. The fifth signal line TL5 may be electrically connected to the first electrode CE1 of one of the pair of third sub-pixels SP3, for example, the 3-1 sub-pixel SP3a. The sixth signal line TL6 may be electrically connected to the first electrode CE1 of the other of the pair of third sub-pixels SP3, for example, the 3-2 sub-pixel SP3b.

The plurality of signal lines TL may be formed of a conductive material. For example, the plurality of signal lines TL may be formed of a conductive material such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO), but the embodiments of the present specification are not limited thereto. For another example, the plurality of signal lines TL may be formed in a multilayer structure of conductive materials. For example, the plurality of signal lines TL may be formed in a multilayer structure of titanium (Ti)/aluminum (Al)/titanium (Ti)/indium tin oxide (ITO), but the embodiments of the present specification are not limited thereto.

The plurality of communication lines NL may be disposed in areas between the plurality of pixels PX. The plurality of communication lines NL may be disposed to extend in a row direction in the areas between the plurality of pixels PX. The plurality of communication lines NL are disposed in areas between the plurality of second electrodes CE2 and may not overlap the plurality of second electrodes CE2. For example, the plurality of communication lines NL may be lines used for short-range communication such as near-field communication (NFC). The plurality of communication lines NL may function as antennas. For example, the plurality of communication lines NL may be a plurality of connection lines or the like, but the embodiments of the present specification are not limited thereto.

According to the present specification, a bank BNK may be disposed in each of the plurality of sub-pixels. The plurality of banks BNK may be structures on which the plurality of light-emitting elements ED are mounted. The plurality of banks BNK may guide the positions of the plurality of light-emitting elements ED in a transfer process of transferring the plurality of light-emitting elements ED to the display device 1000. In the transfer process of the plurality of light-emitting elements ED, the plurality of light-emitting elements ED may be transferred onto the plurality of banks BNK. The plurality of banks BNKs may be bank patterns or structures, but the embodiments of the present specification are not limited thereto.

A bank BNK of the first sub-pixel SP1, a bank BNK of the second sub-pixel SP2, and a bank BNK of the third sub-pixel SP3 may be disposed to be spaced apart from each other. The bank BNK of the first sub-pixel SP1, the bank BNK of the second sub-pixel SP2, and the bank BNK of the third sub-pixel SP3 may be configured to be separated from each other. Thus, the banks BNK of the first sub-pixel SP1, the second sub-pixel SP2, and the third sub-pixel SP3 onto which different types of light-emitting elements ED are transferred may be easily identified.

A bank BNK of the 1-1 sub-pixel SP1a and a bank BNK of the 1-2 sub-pixel SP1b may be connected to each other, or may be spaced apart from each other or separately formed. For example, considering the design requirements or specifications of the transfer process and the like, the bank BNK of the 1-1 sub-pixel SP1a and the bank BNK of the 1-2 sub-pixel SP1b in which the same type of light-emitting elements ED are disposed may be connected to each other, or may be spaced apart or separated from each other. In addition, a bank BNK of the 2-1 sub-pixel SP2a and a bank BNK of the 2-2 sub-pixel SP2b may be connected to each other, or may be spaced apart from each other or separately formed. A bank BNK of the 3-1 sub-pixel SP3a and a bank BNK of the 3-2 sub-pixel SP3b may be connected to each other, or may be spaced apart from each other or separately formed. Accordingly, the banks BNK of the pair of first sub-pixels SP1, the banks BNK of the pair of second sub-pixels SP2, and the banks BNK of the pair of third sub-pixels SP3 may be variously formed, but the embodiments of the present specification are not limited thereto.

For example, the plurality of banks BNK may be formed of an organic insulating material. The plurality of banks BNK may be formed of a single layer or multiple layers of an organic insulating material. For example, the plurality of banks BNK may be formed of photoresist, polyimide (PI), or acrylic materials, but the embodiments of the present specification are not limited thereto.

The first electrode CE1 may be disposed in each of the plurality of sub-pixels. The first electrode CE1 may be disposed on the bank BNK. The first electrode CE1 may be electrically connected to one of the plurality of signal lines TL. At least a portion of the first electrode CE1 may extend outward from the bank BNK to be electrically connected to the signal line TL closest to the first electrode CE1. For example, a portion of the first electrode CE1 of the 1-1 sub-pixel SP1a may extend to one side area of the 1-1 sub-pixel SP1a to be electrically connected to the first signal line TL1, and a portion of the first electrode CE1 of the 1-2 sub-pixel SP1b may extend to the other side area of the 1-2 sub-pixel SP1b to be electrically connected to the second signal line TL2. A portion of the first electrode CE1 of the 2-1 sub-pixel SP2a may extend to one side area of the 2-1 sub-pixel SP2a to be electrically connected to the third signal line TL3, and a portion of the first electrode CE1 of the 2-2 sub-pixel SP2b may extend to the other side area of the 2-2 sub-pixel SP2b to be electrically connected to the fourth signal line TL4. A portion of the first electrode CE1 of the 3-1 sub-pixel SP3a may extend to one side area of the 3-1 sub-pixel SP3a to be electrically connected to the fifth signal line TL5, and a portion of the first electrode CE1 of the 3-2 sub-pixel SP3b may extend to the other side area of the 3-2 sub-pixel SP3b to be electrically connected to the sixth signal line TL6.

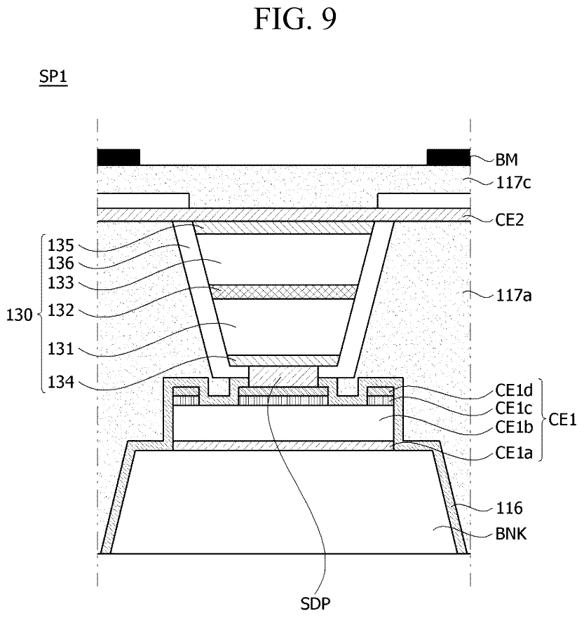

The first electrode CE1 may be electrically connected to the anode 134 (see FIG. 9) of the light-emitting element ED, and may transmit the anode voltage output from the pixel driving circuit PD to the light-emitting element ED through the signal line TL. Different voltages may be applied to the first electrode CE1 of each of the plurality of sub-pixels depending on the displayed image. For example, different voltages may be applied to the first electrode CE1 of each of the plurality of sub-pixels. Accordingly, the first electrode CE1 may be a pixel electrode, but the embodiments of the present specification are not limited thereto.

The first electrode CE1 may be formed of a conductive material. For example, the first electrodes CE1 may be configured integrally with the plurality of signal lines TL. For example, the first electrodes CE1 may be formed of the same conductive material as the plurality of signal lines TL, but the embodiments of the present specification are not limited thereto. For example, the first electrode CE1 may be formed of a conductive material such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO), but the embodiments of the present specification are not limited thereto. For another example, the first electrode CE1 may be formed in a multilayer structure of conductive materials. For example, the plurality of first electrodes CE1 may be formed in a multilayer structure of titanium (Ti)/aluminum (Al)/titanium (Ti)/indium tin oxide (ITO), but the embodiments of the present specification are not limited thereto.

The light-emitting element ED may be disposed in each of the plurality of sub-pixels. Each of the plurality of light-emitting elements ED may be either a light-emitting diode (LED) or a micro light-emitting diode (micro LED), but the embodiments of the present specification are not limited thereto. The plurality of light-emitting elements ED may be disposed on the banks BNK and the first electrodes CE1. The plurality of light-emitting elements ED may be disposed on the first electrodes CE1, and may be electrically connected to the first electrodes CE1. Thus, the light-emitting element ED may emit light by receiving the anode voltage from the pixel driving circuit PD through the signal line TL and the first electrode CE1.

The plurality of light-emitting elements ED may include a first light-emitting element 130, a second light-emitting element 140, and a third light-emitting element 150. The first light-emitting element 130 may be disposed in the first sub-pixel SP1. The second light-emitting element 140 may be disposed in the second sub-pixel SP2. The third light-emitting element 150 may be disposed in the third sub-pixel SP3. For example, one of the first light-emitting element 130, the second light-emitting element 140, and the third light-emitting element 150 may be a red light-emitting element, another one thereof may be a green light-emitting element, and the remaining one thereof may be a blue light-emitting element, but the embodiments of the present specification are not limited thereto. Accordingly, by combining red light, green light, and blue light emitted from the plurality of light-emitting elements ED, various colors of light including white may be implemented. The types of the plurality of light-emitting elements ED are examples, and the embodiments of the present specification are not limited thereto.

The first light-emitting element 130 may include a 1-1 light-emitting element 130a disposed in the 1-1 sub-pixel SP1a and a 1-2 light-emitting element 130b disposed in the 1-2 sub-pixel SP1b. The second light-emitting element 140 may include a 2-1 light-emitting element 140a disposed in the 2-1 sub-pixel SP2a and a 2-2 light-emitting element 140b disposed in the 2-2 sub-pixel SP2b. The third light-emitting element 150 may include a 3-1 light-emitting element 150a disposed in the 3-1 sub-pixel SP3a and a 3-2 light-emitting element 150b disposed in the 3-2 sub-pixel SP3b.

As shown in FIGS. 5 and 6 together with FIG. 7, the second electrode CE2 may be disposed in each of the plurality of sub-pixels. The second electrode CE2 may be disposed on the light-emitting element ED. The second electrodes CE2 may be electrically connected to the pixel driving circuit PD through a plurality of contact electrodes CCE.

For example, the second electrode CE2 may be electrically connected to a cathode 135 (see FIG. 9) of the light-emitting element ED, and may transmit a cathode voltage output from the pixel driving circuit PD to the light-emitting element ED. The same cathode voltage may be applied to the second electrode CE2 of each of the plurality of sub-pixels. For example, the same voltage may be applied to the second electrodes CE2 of the plurality of sub-pixels and the cathode 135 of the light-emitting element ED. Accordingly, the second electrode CE2 may be a common electrode, but the embodiments of the present specification are not limited thereto.

At least some of the plurality of sub-pixels may share the second electrode CE2. At least some of the second electrodes CE2 of the plurality of sub-pixels may be electrically connected to each other. Since the same voltage is applied to the second electrodes CE2, the second electrodes CE2 of at least some of the sub-pixels may be shared. For example, the second electrodes CE2 of at least some of the plurality of pixels PX disposed in the same row may be connected to each other. For example, one second electrode CE2 may be disposed in the plurality of pixels PX. One second electrode CE2 may be disposed for every n sub-pixels.

For example, some of the second electrodes CE2 of the plurality of sub-pixels may be spaced apart from each other or separately disposed. For example, the second electrodes CE2 connected to the pixels PX in an nth row and the second electrodes CE2 connected to the pixels PX in a (n+1)th row may be spaced apart from each other or separately disposed. For example, the plurality of second electrodes CE2 may be disposed to be spaced apart from each other with the plurality of communication lines NL extending in the row direction interposed therebetween. Accordingly, the number of sub-pixels may be greater than the number of second electrodes CE2. For another example, all of the second electrodes CE2 of the plurality of sub-pixels may be interconnected so that only one second electrode CE2 is disposed on the substrate 110, but the embodiments of the present specification are not limited thereto.

The plurality of second electrodes CE2 may be formed of a transparent conductive material, but the embodiments of the present specification are not limited thereto. The plurality of second electrodes CE2 may be formed of a transparent conductive material so that light emitted from the light-emitting elements ED is directed upward through the second electrodes CE2. For example, the second electrode CE2 may be formed of a transparent conductive material such as indium tin oxide (ITO), indium zinc oxide (IZO), or indium gallium zinc oxide (IGZO), but the embodiments of the present specification are not limited thereto.

A plurality of contact electrodes CCE may be disposed on the substrate 110. For example, the plurality of contact electrodes CCE may be disposed to be spaced apart from the plurality of banks BNK and the plurality of signal lines TL. Each of the plurality of second electrodes CE2 may overlap at least one contact electrode CCE. For example, one second electrode CE2 may overlap the plurality of contact electrodes CCE.

For example, the plurality of contact electrodes CCE may be electrically connected to the plurality of second electrodes CE2. The plurality of contact electrodes CCE may be disposed between the substrate 110 and the plurality of second electrodes CE2, and may transmit the cathode voltage output from the pixel driving circuit PD to the second electrodes CE2.

For example, when micro LEDs are used as the light-emitting elements ED, a plurality of micro LEDs may be formed on a wafer and transferred onto the substrate 110 of the display device 1000 to manufacture the display device 1000. During the process of transferring the plurality of light-emitting elements ED having a micro size from the wafer to the substrate 110, various defects may occur. For example, in some sub-pixels, a transfer defect may occur in which the light-emitting element ED is not transferred, and in other sub-pixels, a defect may occur in which the light-emitting element ED is transferred out of an intended position due to misalignment. In addition, although the transfer process proceeds normally, the transferred light-emitting element ED itself may be defective. Thus, in consideration of the defects that may occur during the transfer process of the plurality of light-emitting elements ED, the plurality of light-emitting elements ED of the same type may be transferred onto one sub-pixel. A lighting test may be performed on the plurality of light-emitting elements ED, and ultimately, only one light-emitting element ED that is determined to be normal may be used.

For example, the 1-1 light-emitting element 130a and the 1-2 light-emitting element 130b may be transferred together onto one pixel PX, and may be inspected to determine whether there is a defect. When both the 1-1 light-emitting element 130a and the 1-2 light-emitting element 130b are determined to be normal, only the 1-1 light-emitting element 130a may be used, and the 1-2 light-emitting element 130b may not be used. For another example, when only the 1-2 light-emitting element 130b among the 1-1 light-emitting element 130a and the 1-2 light-emitting element 130b is determined to be normal, the 1-1 light-emitting element 130a may not be used, and only the 1-2 light-emitting element 130b may be used. Accordingly, even when the plurality of light-emitting elements ED of the same type are transferred onto one pixel PX, ultimately, only one light-emitting element ED may be used.

Accordingly, one of the pair of light-emitting elements ED may be a main (or primary) light-emitting element ED, and the other one thereof may be a redundancy light-emitting element ED. The redundancy light-emitting element ED may be a spare light-emitting element ED transferred in preparation for a defective main light-emitting element ED. In the event of a defective main light-emitting element ED, the redundancy light-emitting element ED may be used as a replacement. Accordingly, by transferring both the main light-emitting element ED and the redundancy light-emitting element ED onto one pixel PX, the degradation of display quality due to the failure of the main light-emitting element ED or the redundancy light-emitting element ED may be minimized or suppressed.

For example, the 1-1 light-emitting element 130a, the 2-1 light-emitting element 140a, and the 3-1 light-emitting element 150a transferred onto one pixel PX may be used as main light-emitting elements ED, and the 1-2 light-emitting element 130b, the 2-2 light-emitting element 140b, and the 3-2 light-emitting element 150b transferred onto one pixel PX may be used as redundancy light-emitting elements ED.

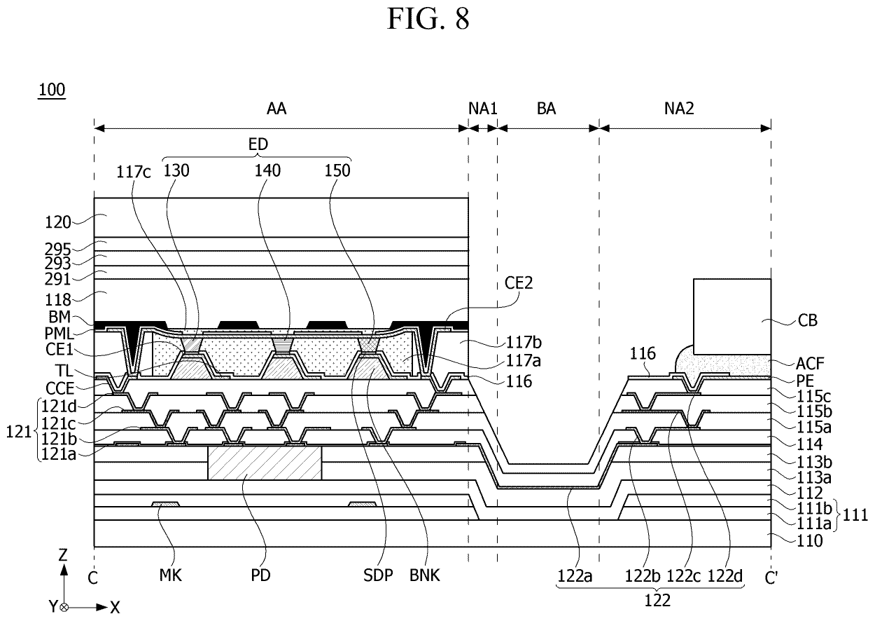

FIG. 8 is a cross-sectional view of the display device according to the example embodiment of the present specification. FIG. 9 is a cross-sectional view of the display device according to an example embodiment of the present specification. For example, FIG. 8 is a cross-sectional view of the display area AA, the first non-display area NA1, the bending area BA, and the second non-display area NA2.

As shown in FIG. 8, a first buffer layer 111a and a second buffer layer 111b may be disposed in the remaining area of the substrate 110, excluding the bending area BA.

The first buffer layer 111a and the second buffer layer 111b may be disposed in the display area AA, the first non-display area NA1, and the second non-display area NA2. The first buffer layer 111a and the second buffer layer 111b may reduce the penetration of moisture or impurities through the substrate 110. The first buffer layer 111a and the second buffer layer 111b may be formed of an inorganic insulating material. For example, the first buffer layer 111a and the second buffer layer 111b may be formed as a single layer or multiple layers of silicon oxide (SiOₓ) or silicon nitride (SiNₓ), but the embodiments of the present specification are not limited thereto.

For example, a portion of the first buffer layer 111a and the second buffer layer 111b located in the bending area BA may be removed. An upper surface of the substrate 110 located in the bending area BA may be exposed from the first buffer layer 111a and the second buffer layer 111b. The first buffer layer 111a and the second buffer layer 111b, which are formed of an inorganic insulating material, may be removed from the bending area BA to minimize or suppress cracks that may occur in the first buffer layer 111a and the second buffer layer 111b during bending.

A plurality of alignment keys MK may be disposed between the first buffer layer 111a and the second buffer layer 111b. The plurality of alignment keys MK may be configured to identify the position of the pixel driving circuit PD during the manufacturing process of the display device 1000. For example, the plurality of alignment keys MK may be configured to align the position of the pixel driving circuit PD that is transferred onto an adhesive layer 112. For another example, the plurality of alignment keys MK may be omitted.

The adhesive layer 112 may be disposed on the second buffer layer 111b. The adhesive layer 112 may be disposed in the display area AA, the first non-display area NA1, the bending area BA, and the second non-display area NA2. For another example, at least a portion of the adhesive layer 112 may be removed from the non-display area NA including the bending area BA. For example, the adhesive layer 112 may be formed of any one of an adhesive polymer, an epoxy resin, an ultraviolet (UV)-curable resin, a polyimide-based material, an acrylate-based material, a urethane-based material, and polydimethylsiloxane (PDMS), but the embodiments of the present specification are not limited thereto.

In the display area AA, the pixel driving circuit PD may be disposed on the adhesive layer 112. When the pixel driving circuit PD is implemented as a driving driver, the driving driver may be mounted on the adhesive layer 112 by a transfer process, but the embodiments of the present specification are not limited thereto.

A first protective layer 113a and a second protective layer 113b may be disposed on the adhesive layer 112 and the pixel driving circuit PD. The first protective layer 113a and the second protective layer 113b may be disposed to surround the side surfaces of the pixel driving circuit PD, but the embodiments of the present specification are not limited thereto. For example, the second protective layer 113b may be disposed to cover at least a portion of an upper surface of the pixel driving circuit PD. For example, at least one of the first protective layer 113a and the second protective layer 113b disposed in the bending area BA may be omitted. For example, the first protective layer 113a may be entirely disposed in the display area AA and the non-display area NA (including the bending area BA), and the second protective layer 113b may be partially disposed in the display area AA, the first non-display area NA1, and the second non-display area NA2. For example, a portion of the second protective layer 113b in the bending area BA may be removed. However, the embodiments of the present specification are not limited thereto.

The first protective layer 113a and the second protective layer 113b may be formed of an organic insulating material, but the embodiments of the present specification are not limited thereto. For example, the first protective layer 113a and the second protective layer 113b may be formed of photoresist, polyimide (PI), photo acrylic materials, or the like, but the embodiments of the present specification are not limited thereto. For example, the first protective layer 113a and the second protective layer 113b may each be an overcoating layer or an insulating layer, but the embodiments of the present specification are not limited thereto.

According to the present specification, a plurality of first connection lines 121 may be disposed on the second protective layer 113b in the display area AA. The plurality of first connection lines 121 may be lines for electrically connecting the pixel driving circuit PD to other components. For example, the pixel driving circuit PD may be electrically connected to the plurality of signal lines TL, the plurality of contact electrodes CCE, and the like through the plurality of first connection lines 121. For example, the plurality of first connection lines 121 may include a 1-1 connection line 121a, a 1-2 connection line 121b, a 1-3 connection line 121c, and a 1-4 connection line 121d, but the embodiments of the present specification are not limited thereto.

For example, a plurality of 1-1 connection lines 121a may be disposed on the second protective layer 113b. The plurality of 1-1 connection lines 121a may be electrically connected to the pixel driving circuit PD. The plurality of 1-1 connection lines 121a may transmit a voltage output from the pixel driving circuit PD to the first electrode CE1 or the second electrode CE2.

For example, a third protective layer 114 may be disposed on the second protective layer 113b. The third protective layer 114 may be entirely disposed in the display area AA and the non-display area NA. In the bending area BA, the third protective layer 114 may cover a side surface of the second protective layer 113b and an upper surface of the first protective layer 113a. The third protective layer 114 may be formed of an organic insulating material. For example, the third protective layer 114 may be formed of photoresist, polyimide (PI), photo acrylic materials, or the like, but the embodiments of the present specification are not limited thereto. For example, the first protective layer 113a, the second protective layer 113b, and the third protective layer 114 may be formed of the same material, but the embodiments of the present specification are not limited thereto.

A plurality of 1-2 connection lines 121b may be disposed on the third protective layer 114. The plurality of 1-2 connection lines 121b may be connected to or directly connected to the pixel driving circuit PD. For example, some of the 1-2 connection lines 121b may be directly connected to the pixel driving circuit PD through contact holes of the third protective layer 114. Another part of the 1-2 connection lines 121b may be electrically connected to the 1-1 connection line 121a through contact holes of the third protective layer 114. However, the embodiments of the present specification are not limited thereto. The voltage output from the pixel driving circuit PD may be transmitted to the first electrode CE1 or the second electrode CE2 through the plurality of 1-2 connection lines 121b and other connection lines.

A first insulating layer 115a may be disposed on the plurality of 1-2 connection lines 121b. The first insulating layer 115a may be entirely disposed in the display area AA and the non-display area NA, but the embodiments of the present specification are not limited thereto. The first insulating layer 115a may be formed of an organic insulating material, but the embodiments of the present specification are not limited thereto. For example, the first insulating layer 115a may be formed of photoresist, polyimide (PI), photo acrylic materials, or the like, but the embodiments of the present specification are not limited thereto.

A plurality of 1-3 connection lines 121c may be disposed on the first insulating layer 115a. The plurality of 1-3 connection lines 121c may be electrically connected to the plurality of 1-2 connection lines 121b. For example, the 1-3 connection lines 121c may be electrically connected to the 1-2 connection lines 121b through contact holes of the first insulating layer 115a.

A second insulating layer 115b may be disposed on the plurality of 1-3 connection lines 121c. The second insulating layer 115b may be disposed in the remaining area excluding the bending area BA, but the embodiments of the present specification are not limited thereto. The second insulating layer 115b may be disposed in the display area AA, the first non-display area NA1, and the second non-display area NA2, but the embodiments of the present specification are not limited thereto. For example, a portion of the second insulating layer 115b disposed in the bending area BA may be removed. The second insulating layer 115b may be formed of an organic insulating material, but the embodiments of the present specification are not limited thereto. For example, the second insulating layer 115b may be formed of photoresist, polyimide (PI), photo acrylic materials, or the like, but the embodiments of the present specification are not limited thereto.

A plurality of 1-4 connection lines 121d may be disposed on the second insulating layer 115b. The plurality of 1-4 connection lines 121d may be electrically connected to the plurality of 1-3 connection lines 121c. For example, the 1-4 connection lines 121d may be electrically connected to the 1-3 connection lines 121c through contact holes of the second insulating layer 115b.

According to the present specification, a plurality of second connection lines 122 may be disposed on the second protective layer 113b in the non-display area NA. The plurality of second connection lines 122 may be lines for transmitting signals, which are transmitted from the flexible circuit board (or flexible film) CB and the printed circuit board 160 (see FIG. 1) to the pad part PAD, to the pixel driving circuit PD of the display area AA. For example, the plurality of second connection lines 122 may be electrically connected to the plurality of pad electrodes PE to receive the signals output from the flexible circuit board (or flexible film) CB and the printed circuit board.

For example, the plurality of second connection lines 122 may extend from the pad part PAD toward the display area AA and may transmit signals to the lines of the display area AA. In this case, the plurality of second connection lines 122 may function as the link lines LL. The plurality of second connection lines 122 may include a 2-1 connection line 122a, a 2-2 connection line 122b, a 2-3 connection line 122c, and a 2-4 connection line 122d.

A plurality of 2-1 connection lines 122a may be disposed on the second protective layer 113b. The plurality of 2-1 connection lines 122a may extend from the second non-display area NA2 to the bending area BA and the first non-display area NA1. The plurality of 2-1 connection lines 122a may transmit signals, which are transmitted to the pad part PAD from the flexible circuit board (or flexible film) CB and the printed circuit board, to the pixel driving circuit PD of the display area AA.

A plurality of 2-2 connection lines 122b may be disposed on the third protective layer 114. The plurality of 2-2 connection lines 122b may be disposed in the second non-display area NA2. The 2-2 connection lines 122b may be electrically connected to the 2-1 connection lines 122a through contact holes of the third protective layer 114. Accordingly, the signals output from the flexible circuit board (or flexible film) CB and the printed circuit board may be transmitted to the 2-1 connection lines 122a through the 2-2 connection lines 122b.

The 2-3 connection line 122c may be disposed on the first insulating layer 115a. The 2-3 connection line 122c may be disposed in the second non-display area NA2. The 2-3 connection line 122c may be electrically connected to the 2-2 connection line 122b through a contact hole of the first insulating layer 115a. Accordingly, the signals output from the flexible circuit board (or flexible film) CB and the printed circuit board may be transmitted to the 2-1 connection lines 122a through the 2-3 connection line 122c and the 2-2 connection lines 122b.

The 2-4 connection line 122d may be disposed on the second insulating layer 115b. The 2-4 connection line 122d may be disposed in the second non-display area NA2. The 2-4 connection line 122d may be electrically connected to the 2-3 connection line 122c through the contact hole of the second insulating layer 115b. Accordingly, the signals output from the flexible circuit board (or flexible film) CB and the printed circuit board may be transmitted to the 2-1 connection lines 122a through the 2-4 connection line 122d, the 2-3 connection line 122c, and the 2-2 connection lines 122b.

The plurality of first connection lines 121 and the plurality of second connection lines 122 may be formed of a highly flexible conductive material or any of the various conductive materials used in the display area AA. For example, the second connection lines 122, some of which are disposed in the bending area BA, may be formed of a highly flexible conductive material such as gold (Au), silver (Ag), or aluminum (Al), but the embodiments of the present specification are not limited thereto. For another example, the plurality of first connection lines 121 and the plurality of second connection lines 122 may be formed of molybdenum (Mo), chromium (Cr), titanium (Ti), nickel (Ni), neodymium (Nd), copper (Cu), an alloy of silver (Ag) and magnesium (Mg), alloys thereof, or the like, but the embodiments of the present specification are not limited thereto.

A third insulating layer 115c may be disposed on the plurality of first connection lines 121 and the plurality of second connection lines 122. The third insulating layer 115c may be disposed in the remaining area excluding the bending area BA, but the embodiments of the present specification are not limited thereto. The third insulating layer 115c may be disposed in the display area AA, the first non-display area NA1, and the second non-display area NA2. A portion of the third insulating layer 115c in the bending area BA may be removed. The third insulating layer 115c may be formed of an organic insulating material, but the embodiments of the present specification are not limited thereto. For example, the third insulating layer 115c may be formed of photoresist, polyimide (PI), photo acrylic materials, or the like, but the embodiments of the present specification are not limited thereto.

In the display area AA, a plurality of banks BNK may be disposed on the third insulating layer 115c. The plurality of banks BNK may be disposed to overlap the plurality of sub-pixels, respectively. At least one or more light-emitting elements ED of the same type may be disposed on each of the plurality of banks BNK.

A plurality of signal lines TL may be disposed on the third insulating layer 115c in the display area AA. The plurality of signal lines TL may be disposed in an area between the plurality of banks BNK. For example, the plurality of signal lines TL may be disposed adjacent to any one of the plurality of banks BNK.

A plurality of contact electrodes CCE may be disposed on the third insulating layer 115c in the display area AA. The plurality of contact electrodes CCE may supply a cathode voltage output from the pixel driving circuit PD to the second electrode CE2.

The first electrode CE1 may be disposed on the bank BNK. For example, the first electrode CE1 may be disposed to extend toward an upper portion of the bank BNK from the adjacent signal line TL. The first electrode CE1 may be disposed on upper and side surfaces of the bank BNK. For example, the first electrode CE1 may be disposed to extend from the signal line TL on an upper surface of the third insulating layer 115c to the side and upper surfaces of the bank BNK.

As shown in FIG. 9, the first electrode CE1 may be composed of a plurality of conductive layers. For example, the first electrode CE1 may include a first conductive layer CEla, a second conductive layer CE1b, a third conductive layer CE1c, and a fourth conductive layer CEld, but the embodiments of the present specification are not limited thereto.

The first conductive layer CEla may be disposed on the bank BNK. The second conductive layer CE1b may be disposed on the first conductive layer CEla. The third conductive layer CElc may be disposed on the second conductive layer CE1b. The fourth conductive layer CEld may be disposed on the third conductive layer CE1c. For example, the first conductive layer CEla, the second conductive layer CE1b, the third conductive layer CE1c, and the fourth conductive layer CEld may each be formed of titanium (Ti), molybdenum (Mo), aluminum (Al), or titanium (Ti) and indium tin oxide (ITO), but the embodiments of the present specification are not limited thereto.

According to the present specification, among the plurality of conductive layers forming the first electrode CE1, some conductive layers with high reflectivity may be configured as alignment keys and/or reflectors for the alignment of the light-emitting element ED. For example, among the plurality of conductive layers of the first electrode CE1, the second conductive layer CElb may include a reflective material. For example, the second conductive layer CE1b may include aluminum (Al), but the embodiments of the present specification are not limited thereto. Accordingly, the second conductive layer CElb may be configured as a reflector. Further, due to the high reflectivity of the second conductive layer CE1b, identification may be facilitated in the manufacturing process, thereby allowing the position or transfer position of the light-emitting element ED to be aligned based on the second conductive layer CE1b.

For example, to configure the second conductive layer CElb as a reflector, the third conductive layer CE1c and the fourth conductive layer CEld covering the second conductive layer CElb may be partially removed or etched. For example, some of the third conductive layer CE1c and the fourth conductive layer CEld disposed on the bank BNK may be removed or etched to expose an upper surface of the second conductive layer CE1b. For example, in each of the third conductive layer CE1c and the fourth conductive layer CEld, a central portion on which the solder pattern SDP is disposed and edge portions may be retained, whereas the remaining portions may be removed. For example, the edge portions of each of the third conductive layer CElc, which is formed of titanium (Ti), and the fourth conductive layer CEld, which is formed of indium tin oxide (ITO), may not be etched. Accordingly, it is possible to prevent or suppress other conductive layers of the first electrode CE1 from being corroded by a tetramethylammonium hydroxide (TMAH) solution used in the masking process of the first electrode CE1.

According to the present specification, the first conductive layer CEla and the third conductive layer CElc may include titanium (Ti) or molybdenum (Mo). The second conductive layer CElb may include aluminum (Al). The fourth conductive layer CEld may include a transparent conductive oxide layer, such as indium tin oxide (ITO) or indium zinc oxide (IZO), which has good adhesion to the solder pattern SDP and exhibits corrosion resistance and acid resistance. However, the embodiments of the present specification are not limited thereto.

The first conductive layer CEla, the second conductive layer CElb, the third conductive layer CE1c, and the fourth conductive layer CEld may be sequentially deposited and then patterned through a photolithography process and an etching process, but the embodiments of the present specification are not limited thereto.

According to the present specification, the signal line TL, contact electrode CCE, and pad electrode PE, which are disposed on the same layer as the first electrode CE1, may be formed as multiple layers of conductive materials, but the embodiments of the present specification are not limited thereto. For example, the signal line TL, the contact electrode CCE, and the pad electrode PE may be formed as multiple layers of indium tin oxide (ITO)/titanium (Ti)/aluminum (Al)/titanium (Ti), but the embodiments of the present specification are not limited thereto.

According to the present specification, the solder pattern SDP may be disposed on the first electrode CE1 in each of the plurality of sub-pixels. The solder pattern SDP may bond the light-emitting element ED to the first electrode CE1. The first electrode CE1 and the light-emitting element ED may be electrically connected through eutectic bonding using the solder pattern SDP, but the embodiments of the present specification are not limited thereto. For example, when the solder pattern SDP is formed of indium (In) and the anode 134 of the light-emitting element ED is formed of gold (Au), the solder pattern SDP and the anode 134 may be bonded by applying heat and pressure during the transfer process of the light-emitting element ED. Through eutectic bonding, the light-emitting element ED may be bonded to the solder pattern SDP and the first electrode CE1 without any additional adhesive. For example, the solder pattern SDP may be formed of indium (In), tin (Sn), or an alloy thereof, but the embodiments of the present specification are not limited thereto. For example, the solder pattern SDP may be a bonding pad, a joining pad, or the like, but the embodiments of the present specification are not limited thereto.

According to the present specification, a passivation layer 116 may be disposed on the plurality of signal lines TL, the plurality of first electrodes CE1, the plurality of contact electrodes CCE, and the third insulating layer 115c. For example, the passivation layer 116 may be disposed in the display area AA, the first non-display area NA1, and the second non-display area NA2. A portion of the passivation layer 116 disposed in the bending area BA may be removed. In the second non-display area NA2, a portion of the passivation layer 116 covering the plurality of pad electrodes PE may be removed. The passivation layer 116 is disposed to cover the remaining areas except for the bending area BA and the area in which the plurality of pad electrodes PE and the solder pattern SDP are disposed, thereby reducing the penetration of moisture or impurities into the light-emitting element ED. For example, the passivation layer 116 may be formed as a single layer or multiple layers of silicon oxide (SiOₓ) or silicon nitride (SiNₓ), but the embodiments of the present specification are not limited thereto. For example, the passivation layer 116 may be a protective layer, an insulating layer, or the like, but the embodiments of the present specification are not limited thereto. For example, the passivation layer 116 may include a hole that exposes the solder pattern SDP.

In each of the plurality of sub-pixels, the light-emitting element ED may be disposed on the solder pattern SDP. In the first sub-pixel SP1, the first light-emitting element 130 may be disposed. In the second sub-pixel SP2, the second light-emitting element 140 may be disposed. The third light-emitting element 150 disposed in the third sub-pixel SP3.

The light-emitting element ED may be formed on a silicon wafer using methods such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering, but the embodiments of the present specification are not limited thereto.

As shown in FIG. 9, the first light-emitting element 130 may include an anode 134, a first semiconductor layer 131, an active layer 132, a second semiconductor layer 133, a cathode 135, and an encapsulation film 136, but the embodiments of the present specification are not limited thereto. For example, the first light-emitting element 130 may not include the encapsulation film 136.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented as a group III-V compound semiconductor, a group II-VI compound semiconductor, or the like and may be doped with impurities (or dopants). For example, one of the first semiconductor layer 131 and the second semiconductor layer 133 may be a semiconductor layer doped with n-type impurities, and the other may be a semiconductor layer doped with p-type impurities, but the embodiments of the present specification are not limited thereto. For example, one or more of the first semiconductor layer 131 and the second semiconductor layer 133 may be a layer doped with n-type or p-type impurities in a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), gallium arsenide (GaAs), or the like, but the embodiments of the present specification are not limited thereto. For example, the n-type impurities may include silicon (Si), germanium (Ge), selenium (Se), carbon (C), tellurium (Te), tin (Sn), and the like, but the embodiments of the present specification are not limited thereto. For example, the p-type impurities may include magnesium (Mg), zinc (Zn), calcium (Ca), strontium (Sr), barium (Ba), beryllium (Be), and the like, but the embodiments of the present specification are not limited thereto.

For example, the first semiconductor layer 131 and the second semiconductor layer 133 may be a nitride semiconductor containing n-type impurities and a nitride semiconductor containing p-type impurities, respectively, but the embodiments of the present specification are not limited thereto. For example, the first semiconductor layer 131 may be a nitride semiconductor containing p-type impurities, and the second semiconductor layer 133 may be a nitride semiconductor containing n-type impurities, but the embodiments of the present specification are not limited thereto.

The active layer 132 may be disposed between the first semiconductor layer 131 and the second semiconductor layer 133. The active layer 132 may emit light by receiving holes and electrons from the first semiconductor layer 131 and the second semiconductor layer 133. For example, the active layer 132 may include one of a single well structure, a multi-well structure, a single quantum well structure, a multi-quantum well (MQW) structure, a quantum dot structure, and a quantum wire structure, but the embodiments of the present specification are not limited thereto. For example, the active layer 132 may be formed of indium gallium nitride (InGaN), gallium nitride (GaN), or the like, but the embodiments of the present specification are not limited thereto.

For another example, the active layer 132 may include a multi-quantum well (MQW) structure having a well layer and a barrier layer with a higher bandgap than the well layer. For example, the active layer 132 may include an InGaN well layer and an AlGaN barrier layer, but the embodiments of the present specification are not limited thereto.

The anode 134 may be disposed between the first semiconductor layer 131 and the solder pattern SDP. For example, the anode 134 may electrically connect the first semiconductor layer 131 and the first electrode CE1. An anode voltage output from the pixel driving circuit PD may be applied to the first semiconductor layer 131 through the signal line TL, the first electrode CE1, and the anode 134. For example, the anode 134 may be formed of a conductive material capable of eutectic bonding with the solder pattern SDP, but the embodiments of the present specification are not limited thereto. For example, the anode 134 may be formed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or an alloy thereof, but the embodiments of the present specification are not limited thereto.

The cathode 135 may be disposed on the second semiconductor layer 133. For example, the cathode 135 may electrically connect the second semiconductor layer 133 and the second electrode CE2. A cathode voltage output from the pixel driving circuit PD may be applied to the second semiconductor layer 133 through the contact electrode CCE, the second electrode CE2, and the cathode 135. The cathode 135 may be formed of a transparent conductive material to allow light emitted from the light-emitting element ED to be directed upward, but the embodiments of the present specification are not limited thereto. For example, the cathode 135 may be formed of a material such as indium tin oxide (ITO), indium zinc oxide (IZO), or indium gallium zinc oxide (IGZO), but the embodiments of the present specification are not limited thereto.

The encapsulation film 136 may be disposed on at least some of the first semiconductor layer 131, the active layer 132, the second semiconductor layer 133, the anode 134, and the cathode 135. For example, the encapsulation film 136 may surround at least some of the first semiconductor layer 131, the active layer 132, the second semiconductor layer 133, the anode 134, and the cathode 135.

The encapsulation film 136 may protect the first semiconductor layer 131, the active layer 132, and the second semiconductor layer 133. For example, the encapsulation film 136 may be disposed on the side surfaces of the first semiconductor layer 131, the active layer 132, and the second semiconductor layer 133.

For example, the encapsulation film 136 may be disposed on at least a portion of each of the anode 134 and the cathode 135, for example, on an edge portion (or one side) of the anode 134 and an edge portion (or one side) of the cathode 135. At least a portion of the anode 134 may be exposed from the encapsulation film 136, thereby allowing the anode 134 to be connected to the solder pattern SDP. For example, at least a portion of the cathode 135 may be exposed from the encapsulation film 136, thereby allowing the cathode 135 to be connected to the second electrode CE2. For example, the encapsulation film 136 may be formed of an insulating material such as silicon nitride (SiNₓ) or silicon oxide (SiOₓ), but the embodiments of the present specification are not limited thereto.

For another example, the encapsulation film 136 may have a structure in which a reflective material is dispersed in a resin layer, but the embodiments of the present specification are not limited thereto. For example, the encapsulation film 136 may be fabricated as a reflector with various structures, but the embodiments of the present specification are not limited thereto. Light emitted from the active layer 132 may be reflected upward by the encapsulation film 136, thereby enhancing light extraction efficiency. For example, the encapsulation film 136 may be a reflective layer, but the embodiments of the present specification are not limited thereto.

According to the present specification, the light-emitting element ED has been described as having a vertical structure, but the embodiments of the present specification are not limited thereto. For example, the light-emitting element ED may have a lateral structure or a flip chip structure.

Although the first light-emitting element 130 has been described with reference to FIG. 9, but the second light-emitting element 140 and the third light-emitting element 150 may have substantially the same structure as the first light-emitting element 130. For example, the second light-emitting element 140 and the third light-emitting element 150 may have substantially the same structure as the first semiconductor layer 131, the active layer 132, the second semiconductor layer 133, the anode 134, the cathode 135, and the encapsulation film 136 of the first light-emitting element 130.

According to the present specification, first optical layers 117a surrounding the plurality of light-emitting elements ED in the display area AA may be disposed. For example, the first optical layers 117a may be disposed to cover the plurality of light-emitting elements ED and the banks BNK in the areas of the plurality of sub-pixels. For example, the first optical layers 117a may cover the banks BNK, a portion of the passivation layer 116, and spaces between the plurality of light-emitting elements ED. The first optical layers 117a may be disposed or may cover the spaces between the plurality of light-emitting elements ED included in one pixel PX and between the plurality of banks BNK. For example, the first optical layers 117a may extend in the first direction X and may be disposed spaced apart in the second direction Y. For example, the first optical layer 117a may be disposed to surround the side portions of the light-emitting element ED and the bank BNK between the passivation layer 116 and the second electrode CE2, but the embodiments of the present specification are not limited thereto. For example, the first optical layer 117a may be a diffusion layer, a sidewall diffusion layer, or the like, but the embodiments of the present specification are not limited thereto.

The first optical layer 117a may include an organic insulating material in which fine particles are dispersed, but the embodiments of the present specification are not limited thereto. For example, the first optical layer 117a may be formed of siloxane in which fine metal particles, such as titanium dioxide (TiO₂) particles, are dispersed, but the embodiments of the present specification are not limited thereto. Light emitted from the plurality of light-emitting elements ED may be scattered by the fine particles dispersed in the first optical layer 117a and emitted to the outside of the display device 1000. Accordingly, the first optical layer 117a may improve the extraction efficiency of the light emitted from the plurality of light-emitting elements ED.

For example, the first optical layer 117a may be disposed in each of the plurality of pixels PX, or the first optical layers 117a may be disposed together with some of the pixels PX disposed in the same row, but the embodiments of the present specification are not limited thereto. For example, the first optical layer 117a may be disposed in each of the plurality of pixels PX, or the plurality of pixels PX may share one first optical layer 117a. For another example, each of the plurality of sub-pixels may separately include the first optical layer 117a, but the embodiments of the present specification are not limited thereto.

According to the present specification, a second optical layer 117b may be disposed on the passivation layer 116 in the display area AA. For example, the second optical layer 117b may be disposed to surround the first optical layer 117a. For example, the second optical layer 117b may be in contact with a side surface of the first optical layer 117a. For example, the second optical layer 117b may be disposed in the area between the plurality of pixels PX. However, the embodiments of the present specification are not limited thereto, and for example, the second optical layer 117b may be a diffusion layer, a diffusion layer window, a window diffusion layer, or the like, but the embodiments of the present specification are not limited thereto.

The second optical layer 117b may be formed of an organic insulating material, but the embodiments of the present specification are not limited thereto. The second optical layer 117b may be formed of the same material as the first optical layer 117a, but the embodiments of the present specification are not limited thereto. For example, the first optical layer 117a may include fine particles, and the second optical layer 117b may not include fine particles. For example, the second optical layer 117b may be formed of siloxane, but the embodiments of the present specification are not limited thereto.

For example, a thickness of the first optical layer 117a may be less than a thickness of the second optical layer 117b, but the embodiments of the present specification are not limited thereto. Accordingly, when viewed in a plan view, an area in which the first optical layer 117a is disposed may include a recessed portion that is recessed inward relative to an upper surface of the second optical layer 117b.

According to the present specification, the second electrode CE2 may be disposed on the first optical layer 117a and the second optical layer 117b. For example, the second electrode CE2 may be electrically connected to the plurality of contact electrodes CCE through a contact hole of the second optical layer 117b. For example, the second electrode CE2 may be disposed on the plurality of light-emitting elements ED. For example, the second electrode CE2 may include a transparent conductive oxide such as indium tin oxide (ITO) or indium zinc oxide (IZO), but the embodiments of the present specification are not limited thereto. For example, the second electrode CE2 may be disposed to be in contact with the cathode 135. For example, the second electrode CE2 may overlap the first optical layer 117a. For example, the second electrode CE2 may cover a plane on an outer side of the first optical layer 117a.

The second electrode CE2 may continuously extend in the first direction X of the substrate 110. Accordingly, the second electrode CE2 may be commonly connected to the plurality of pixels PX arranged in the first direction X of the substrate 110. For example, the second electrode CE2 may be commonly connected to a plurality of pixels PX.

According to the present specification, the second electrode CE2 may continuously extend on the first optical layer 117a, the second optical layer 117b, and the light-emitting element ED. The area in which the first optical layer 117a is disposed may include a recessed portion that is recessed inward relative to the upper surface of the second optical layer 117b. Accordingly, since a first portion of the second electrode CE2 disposed on the first optical layer 117a is disposed along the recessed portion, the first portion of the second electrode CE2 may be disposed at a position lower than that of a second portion of the second electrode CE2 disposed on the second optical layer 117b.

A third optical layer 117c may be disposed on the second electrode CE2. The third optical layer 117c may be disposed to overlap the plurality of light-emitting elements ED and the first optical layer 117a. Since the third optical layer 117c is disposed on the second electrode CE2 and the plurality of light-emitting elements ED, the third optical layer 117c may improve the mura that may occur in some of the plurality of light-emitting elements ED. For example, when transferring the plurality of light-emitting elements ED onto the substrate 110 of the display device 1000, an area in which intervals between the plurality of light-emitting elements ED are not uniform may occur due to process variations or the like. When the intervals between the plurality of light-emitting elements ED are not uniform, light emission areas of each of the plurality of light-emitting elements ED may be disposed unevenly, which may cause a user to perceive mura. Accordingly, by configuring the third optical layer 117c to uniformly diffuse light over the plurality of light-emitting elements ED, the occurrence of light emitted from some light-emitting elements ED appearing as mura can be reduced. Accordingly, the light emitted from the plurality of light-emitting elements ED is evenly diffused by the third optical layer 117c and extracted to the outside of the display device 1000, thereby improving the luminance uniformity of the display device 1000.

The third optical layer 117c may be formed of an organic insulating material in which fine particles are dispersed, but the embodiments of the present specification are not limited thereto. For example, the third optical layer 117c may be formed of siloxane in which fine metal particles, such as titanium dioxide (TiO₂) particles, are dispersed, but the embodiments of the present specification are not limited thereto. For example, the third optical layer 117c may be formed of the same material as the first optical layer 117a, but the embodiments of the present specification are not limited thereto. For example, the third optical layer 117c may be a diffusion layer, an upper diffusion layer, or the like, but the embodiments of the present specification are not limited thereto.

According to the present specification, light emitted from the plurality of light-emitting elements ED may be scattered by the fine particles dispersed in the third optical layer 117c and emitted to the outside of the display device 1000. The third optical layer 117c may evenly mix the light emitted from the plurality of light-emitting elements ED, thereby further improving the luminance uniformity of the display device 1000. In addition, the light extraction efficiency of the display device 1000 may be improved by the light scattered from the plurality of fine particles, thereby enabling the display device 1000 to operate at lower power.

In the display area AA, the black matrix BM may be disposed on the second electrode CE2, the first optical layer 117a, the second optical layer 117b, and the third optical layer 117c. For example, the contact hole of the second optical layer 117b may be filled with the black matrix BM. The black matrix BM is configured to cover the display area AA, and thus may reduce the color mixing of light from the plurality of sub-pixels and the reflection of external light.

For example, the black matrix BM may be formed of an opaque material, but the embodiments of the present specification are not limited thereto. For example, the black matrix BM may be an organic insulating material containing a black pigment or a black dye, but the embodiments of the present specification are not limited thereto.

In the display area AA, a cover layer 118 may be disposed on the black matrix BM. The cover layer 118 may protect the configuration below the cover layer 118, and for example, the cover layer 118 may be formed of an organic insulating material, but the embodiments of the present specification are not limited thereto. For example, the cover layer 118 may be formed of photoresist, polyimide (PI), photo acrylic materials, or the like, but the embodiments of the present specification are not limited thereto. For example, the cover layer 118 may be an overcoating layer, an insulating layer, or the like, but the embodiments of the present specification are not limited thereto.

According to the present disclosure, in the display area AA, an additional passivation layer PML is further formed below the black matrix BM to minimize or at least reduce moisture permeation. The additional passivation layer PML can be disposed between the third optical layer 117c and the second electrode CE2 in the active area AA. The additional passivation layer PML can be disposed to cover the second electrode CE2 as well as the first optical layer 117a and the second optical layer 117b. Therefore, the additional passivation layer PML overlaps with the second electrode CE2, the first optical layer 117a, and the second optical layer 117b. The additional passivation layer PML is an inorganic insulating layer which is formed of an inorganic insulating material and may more easily block the moisture than the other insulating layer which is formed of an organic insulating material. For example, the additional passivation layer PML may be configured by a single layer or a double layer of silicon oxide (SiOₓ) or silicon nitride (SiNₓ), but is not limited thereto. The additional passivation layer PML includes a plurality of openings that overlap with the plurality of light-emitting elements ED, thereby preventing or suppressing a reduction in the light emission efficiency of the plurality of light-emitting elements ED.

The polarizing layer 293 may be disposed on the cover layer 118 via a first adhesive layer 291. The cover member 120 may be disposed on the polarizing layer 293 via a second adhesive layer 295. For example, the first adhesive layer 291 and the second adhesive layer 295 may include an optically clear adhesive (OCA), an optically clear resin (OCR), a pressure sensitive adhesive (PSA), or the like, but the embodiments of the present specification are not limited thereto.

According to the present specification, a plurality of pad electrodes PE may be disposed on the third insulating layer 115c in the second non-display area NA2. For example, at least some of the plurality of pad electrodes PE may be exposed from the passivation layer 116. For example, the plurality of pad electrodes PE may be electrically connected to the 2-4 connection line 122d through contact holes of the third insulating layer 115c.

A conductive adhesive layer ACF may be disposed on the plurality of pad electrodes PE. The conductive adhesive layer ACF may be an adhesive layer in which conductive balls are dispersed in an insulating material, but the embodiments of the present specification are not limited thereto. When heat or pressure is applied to the conductive adhesive layer ACF, the conductive balls at the portions to which the heat or pressure is applied may become electrically connected, thereby exhibiting conductive properties. The conductive adhesive layer ACF may be disposed between the plurality of pad electrodes PE and the flexible circuit board (or flexible film) CB, thereby allowing the flexible circuit board (or flexible film) CB to be attached or bonded to the plurality of pad electrodes PE. For example, the conductive adhesive layer ACF may be an anisotropic conductive film (ACF), but the embodiments of the present specification are not limited thereto.

The flexible circuit board (or flexible film) CB may be disposed on the conductive adhesive layer ACF. The flexible circuit board (or flexible film) CB may be electrically connected to the plurality of pad electrodes PE through the conductive adhesive layer ACF. Accordingly, signals output from the flexible circuit board (or flexible film) CB and the printed circuit board may be transmitted to the pixel driving circuit PD of the display area AA through the plurality of pad electrodes PE, and the 2-4 connection line 122d, the 2-3 connection line 122c, the 2-2 connection line 122b, and the 2-1 connection line 122a.

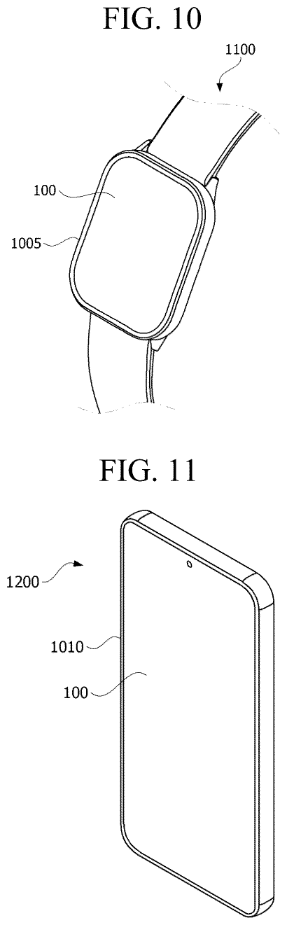

FIGS. 10 to 13 are views illustrating devices to which the display device according to example embodiments of the present specification is applied.

As shown in FIGS. 10 to 13, the display device 1000 according to example embodiments of the present specification may be included in various devices or electronic devices. For example, as shown in FIGS. 10 to 13, the various electronic devices may include a wearable device 1100, a mobile device 1200, a laptop 1300, and a monitor or TV 1400, but the embodiments of the present specification are not limited thereto.

The wearable device 1100, the mobile device 1200, the laptop 1300, and the monitor or TV 1400 may include case parts 1005, 1010, 1015, and 1020, respectively, and may each include the display panel 100 and the display device 1000 according to example embodiments of the present specification described with reference to FIGS. 1 to 9.

For example, the display device according to the embodiment of the present specification may be applied to mobile devices, video phones, smart watches, watch phones, wearable apparatuses, foldable apparatuses, rollable apparatuses, bendable apparatuses, flexible apparatuses, curved apparatuses, sliding apparatuses, variable apparatuses, electronic organizers, e-books, portable multimedia players (PMPs), personal digital assistants (PDAs), MP3 players, mobile medical devices, desktop personal computers (PCs) s, laptop PCs, netbook computers, workstations, navigation devices, vehicle display apparatuses, theater display apparatuses, televisions, wallpaper devices, signage devices, gaming devices, laptops, monitors, cameras, camcorders, household appliances, and the like.

Hereinafter, a display device (or display panel) and a method of manufacturing the same according to an example embodiment of the present specification will be described.

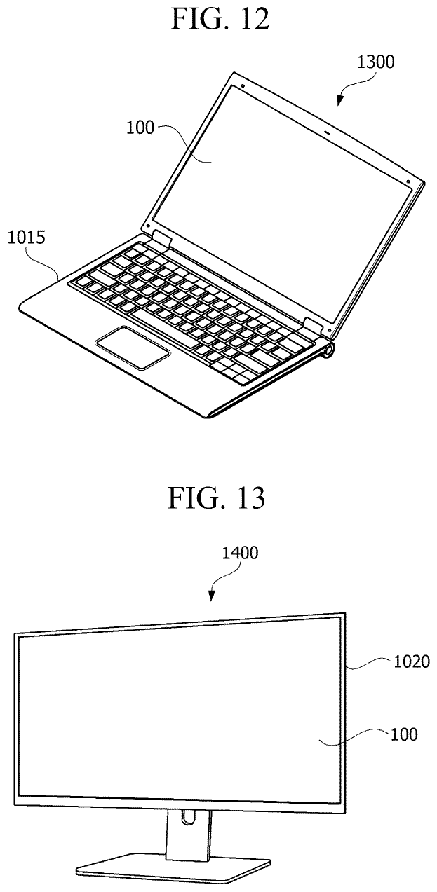

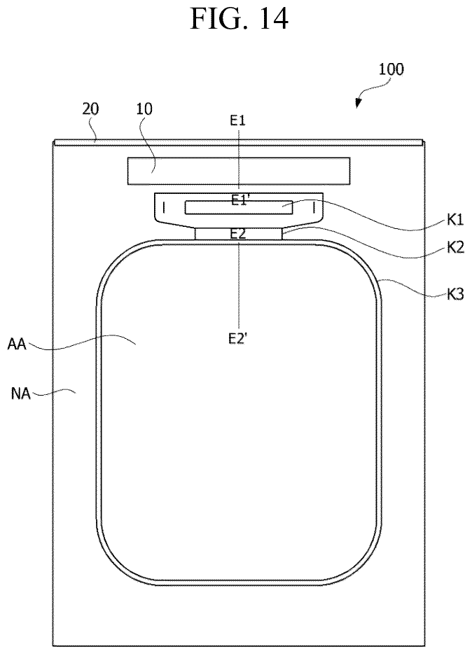

FIGS. 14 and 15 are a plan view and a cross-sectional view, respectively, of a display panel according to an example embodiment of the present specification. FIG. 15 illustrates cross-sectional views of the display panel of FIG. 14, taken along lines E1-E1′ and E2-E2′.

As shown in FIGS. 14 and 15, a display panel 100 according to an example embodiment of the present specification may include a display area AA, a test pad 10, and a shorting bar 20. The test pad 10 and the shorting bar 20 may be disposed in a non-display area NA, which is an area outside the display area AA.

For a test process performed during a manufacturing process of the display panel, test pads connected to driving-related signal lines disposed in the display panel are disposed inside the display panel, and the test process may be performed using the disposed test pads. In this case, the test pads may remain on the display panel after the manufacturing process is finally completed.

The test pad 10 may be disposed at an upper end of the display area AA and include a plurality of test pads. A connection line SL disposed in the non-display area NA may be connected to the test pad 10. The connection line SL in the non-display area NA is electrically connected to a signal line TL disposed in the display area AA and through which signals from a driving driver 30 are transmitted, thereby allowing an electrical state of the connection line SL to be tested through the test pad 10. In one embodiment, the display panel 100 may include micro LEDs, and the electrical state of the signal line TL, through which signals for driving the micro LEDs are transmitted, may be tested through the test pad 10.

The shorting bar 20 may be disposed near the test pad 10. For example, the shorting bar 20 may be disposed at an upper end of the test pad 10. During an in-process test (IPT) performed in the manufacturing process of the display panel, electrostatic discharge (ESD) may be generated and induced to the shorting bar 20, thereby preventing or suppressing damage to the display device due to ESD.

For example, during a deposition process of a material layer used in the manufacture of the display panel 100, ESD may occur when charges accumulated on the display panel 100 inside a process chamber are discharged as the process chamber is opened.

A film on panel (FOP) pad K1 may be an area to which a test chip is bonded. A bending area K2 may be an area that is folded to conceal parts related to testing during the operation of the display panel. A trimming area K3 may be an area in which the display area is trimmed.

A portion of an indium layer F4 may be a layer formed or deposited on a reverse-taper pattern area. Pattern areas may be formed on an organic film layer F5 through an exposure process.

As shown in FIG. 15, a first buffer layer 111a and a second buffer layer 111b may be disposed in the display area AA and the non-display area NA of a substrate 110.

The first buffer layer 111a and the second buffer layer 111b may be disposed in the display area AA, the test pad 10, and the shorting bar 20. The first buffer layer 111a and the second buffer layer 111b may reduce the penetration of moisture or impurities through the substrate 110. The first buffer layer 111a and the second buffer layer 111b may each be formed of an inorganic insulating material. For example, the first buffer layer 111a and the second buffer layer 111b may each be formed as a single layer or multiple layers of silicon oxide (SiOₓ) or silicon nitride (SiNₓ), but the embodiments of the present specification are not limited thereto.

An adhesive layer 112 may be disposed on the second buffer layer 111b. The adhesive layer 112 may be disposed in the display area AA, the test pad 10, and the shorting bar 20. For example, the adhesive layer 112 may be formed of any one of an adhesive polymer, an epoxy resin, an ultraviolet (UV)-curable resin, a polyimide-based material, an acrylate-based material, a urethane-based material, and polydimethylsiloxane (PDMS), but the embodiments of the present specification are not limited thereto.

In the display area AA, the driving driver 30 may be disposed on the adhesive layer 112. In one embodiment, the driving driver 30 may be mounted on the adhesive layer 112 through a transfer process, but the embodiments of the present specification are not limited thereto.

A first protective layer 113a and a second protective layer 113b may be disposed on the adhesive layer 112 and the driving driver 30. The first protective layer 113a and the second protective layer 113b may be disposed to surround a side surface of the driving driver 30, but the embodiments of the present specification are not limited thereto. For example, the second protective layer 113b may be disposed to cover at least a portion of an upper surface of the driving driver 30. For example, the first protective layer 113a and the second protective layer 113b may be disposed in the display area AA, the test pad 10, and the shorting bar 20.

The first protective layer 113a and the second protective layer 113b may each be formed of an organic insulating material, but the embodiments of the present specification are not limited thereto. For example, the first protective layer 113a and the second protective layer 113b may each be formed of photoresist, polyimide (PI), photo acrylic materials, or the like, but the embodiments of the present specification are not limited thereto. For example, the first protective layer 113a and the second protective layer 113b may each be an overcoating layer or an insulating layer, but the embodiments of the present specification are not limited thereto.

According to the present specification, a plurality of first connection lines 121 may be disposed on the second protective layer 113b in the display area AA. The plurality of first connection lines 121 may be lines for electrically connecting the driving driver 30 to other components. For example, the driving driver 30 may be electrically connected to a plurality of signal lines TL, a plurality of contact electrodes CCE, and the like through the plurality of first connection lines 121. For example, the plurality of first connection lines 121 may include a 1-1 connection line 121a, a 1-2 connection line 121b, a 1-3 connection line 121c, and a 1-4 connection line 121d, but the embodiments of the present specification are not limited thereto.

For example, a plurality of 1-1 connection lines 121a may be disposed on the second protective layer 113b. The plurality of 1-1 connection lines 121a may be electrically connected to the driving driver 30. The plurality of 1-1 connection lines 121a may transmit voltages output from the driving driver 30 to the electrodes.

For example, a third protective layer 114 may be disposed on the second protective layer 113b. The third protective layer 114 may be disposed in the display area AA, the test pad 10, and the shorting bar 20. The third protective layer 114 may be formed of an organic insulating material. For example, the third protective layer 114 may be formed of photoresist, polyimide (PI), photo acrylic materials, or the like, but the embodiments of the present specification are not limited thereto. For example, the first protective layer 113a, the second protective layer 113b, and the third protective layer 114 may be formed of the same material, but the embodiments of the present specification are not limited thereto.

A plurality of 1-2 connection lines 121b may be disposed on the third protective layer 114. The plurality of 1-2 connection lines 121b may be connected to or directly connected to the driving driver 30. For example, some of the 1-2 connection lines 121b may be directly connected to the driving driver 30 through contact holes of the third protective layer 114. Another part of the 1-2 connection lines 121b may be electrically connected to the 1-1 connection line 121a through contact holes of the third protective layer 114. However, the embodiments of the present specification are not limited thereto. The voltages output from the driving driver 30 may be transmitted to the electrodes through the plurality of 1-2 connection lines 121b and other connection lines.

A first insulating layer 115a may be disposed on the plurality of 1-2 connection lines 121b. The first insulating layer 115a may be entirely disposed in the display area AA, the test pad 10, and the shorting bar 20, but the embodiments of the present specification are not limited thereto. The first insulating layer 115a may be formed of an organic insulating material, but the embodiments of the present specification are not limited thereto. For example, the first insulating layer 115a may be formed of photoresist, polyimide (PI), photo acrylic materials, or the like, but the embodiments of the present specification are not limited thereto.

A plurality of 1-3 connection lines 121c may be disposed on the first insulating layer 115a. The plurality of 1-3 connection lines 121c may be electrically connected to the plurality of 1-2 connection lines 121b. For example, the 1-3 connection lines 121c may be electrically connected to the 1-2 connection lines 121b through contact holes of the first insulating layer 115a.

A second insulating layer 115b may be disposed on the plurality of 1-3 connection lines 121c. The second insulating layer 115b may be disposed in the display area AA, the test pad 10, and the shorting bar 20, but the embodiments of the present specification are not limited thereto. The second insulating layer 115b may be formed of an organic insulating material, but the embodiments of the present specification are not limited thereto. For example, the second insulating layer 115b may be formed of photoresist, polyimide (PI), photo acrylic materials, or the like, but the embodiments of the present specification are not limited thereto.

A plurality of 1-4 connection lines 121d may be disposed on the second insulating layer 115b. The plurality of 1-4 connection lines 121d may be electrically connected to the plurality of 1-3 connection lines 121c. For example, the 1-4 connection lines 121d may be electrically connected to the 1-3 connection lines 121c through contact holes of the second insulating layer 115b.

A plurality of second connection lines 122 may be lines connected to the plurality of first connection lines 121, which are lines for electrically connecting the driving driver 30 to other components. For example, the plurality of second connection lines 122 may be connected to the plurality of first connection lines 121 through the plurality of connection lines SL and may receive signals from the driving driver 30.

For example, the plurality of second connection lines 122 may extend toward the non-display area NA and transmit signals to lines associated with the test pad 10 of the non-display area NA. The plurality of second connection lines 122 may include a 2-1 connection line 122a, a 2-2 connection line 122b, a 2-3 connection line 122c, and a 2-4 connection line 122d.

A plurality of 2-1 connection lines 122a may be disposed on the second protective layer 113b. The plurality of 2-1 connection lines 122a may be disposed in the test pad 10 and the shorting bar 20. The plurality of 2-1 connection lines 122a may transmit signals transmitted from the driving driver 30 to the test pad 10 of the non-display area NA.

A plurality of 2-2 connection lines 122b may be disposed on the third protective layer 114. The plurality of 2-2 connection lines 122b may be disposed in the test pad 10 and the shorting bar 20. The 2-2 connection lines 122b may be electrically connected to the 2-1 connection lines 122a through contact holes of the third protective layer 114. Accordingly, the signals output from the driving driver 30 may be transmitted to the 2-2 connection lines 122b through the 2-1 connection lines 122a.

The 2-3 connection line 122c may be disposed on the first insulating layer 115a. The 2-3 connection line 122c may be disposed in the test pad 10 and the shorting bar 20. The 2-3 connection line 122c may be electrically connected to the 2-2 connection line 122b through a contact hole of the first insulating layer 115a. Accordingly, the signal output from the driving driver 30 may be transmitted to the 2-3 connection line 122c through the 2-1 connection line 122a and the 2-2 connection line 122b.

The 2-4 connection line 122d may be disposed on the second insulating layer 115b. The 2-4 connection line 122d may be disposed in the test pad 10 and the shorting bar 20. The 2-4 connection line 122d may be electrically connected to the 2-3 connection line 122c through the contact hole of the second insulating layer 115b. Accordingly, the signal output from the driving driver 30 may be transmitted to the 2-4 connection line 122d through the 2-1 connection line 122a, the 2-2 connection line 122b, and the 2-3 connection line 122c.

The plurality of first connection lines 121 and the plurality of second connection lines 122 may be formed of a highly flexible conductive material or any of the various conductive materials used in the display area AA or the non-display area NA. For example, the plurality of first connection lines 121 and the plurality of second connection lines 122 may be formed of molybdenum (Mo), chromium (Cr), titanium (Ti), nickel (Ni), neodymium (Nd), copper (Cu), an alloy of silver (Ag) and magnesium (Mg), alloys thereof, or the like, but the embodiments of the present specification are not limited thereto.

A third insulating layer 115c may be disposed on the plurality of first connection lines 121 and the plurality of second connection lines 122. The third insulating layer 115c may be disposed in the display area AA, the test pad 10, and the shorting bar 20. The third insulating layer 115c may be formed of an organic insulating material, but the embodiments of the present specification are not limited thereto. For example, the third insulating layer 115c may be formed of photoresist, polyimide (PI), photo acrylic materials, or the like, but the embodiments of the present specification are not limited thereto.

The plurality of first connection lines 121 in the display area AA and the plurality of second connection lines 122 in the test pad 10 and the shorting bar 20 as described above may be portions of connection lines SL for transmitting signals from the driving driver 30. For example, the signal lines TL may include M0 to M4 layers, but the embodiments of the present specification are not limited thereto. The M0 layer may be the 1-1 connection line 121a of FIG. 15. The M1 layer may be the 1-2 connection line 121b of FIG. 15. The M2 layer may be the 1-3 connection line 121c of FIG. 15. The M3 layer may be the 1-4 connection line 121d of FIG. 15. As shown in region 1 of FIG. 15, in one embodiment, the M4 layer may be a layer formed to extend over a bank BNK, and electrically connected to the indium layer F4, which is deposited on the pattern area formed on the organic film layer F5 by coming into contact with the indium layer F4. In a subsequent process, a second layer L2 on the bank BNK may be a layer to which a light-emitting element (e.g., a micro LED) is bonded.

Hereinafter, a method for reducing defects caused by electrostatic discharge (ESD) at the test pad 10 may be described.

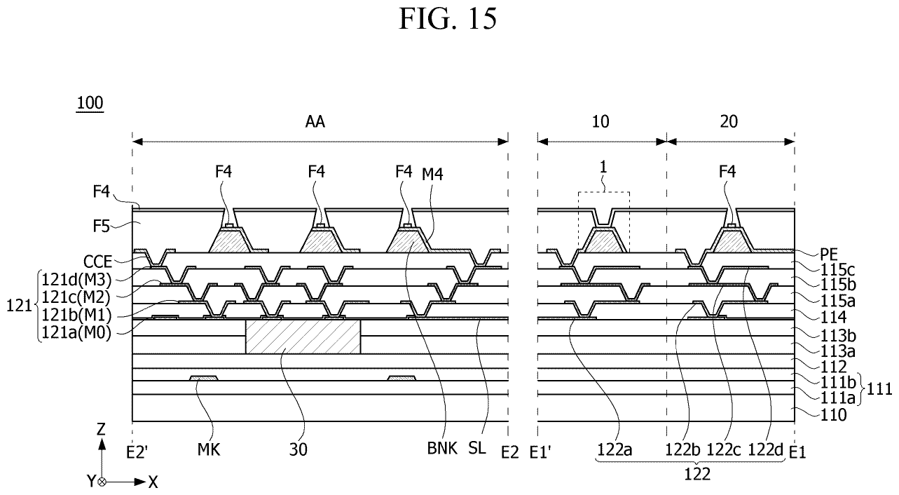

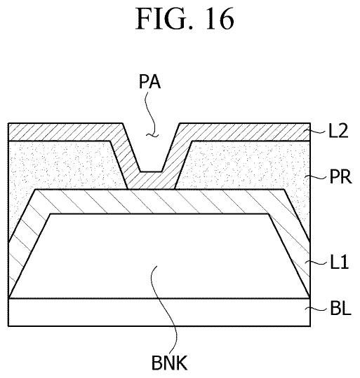

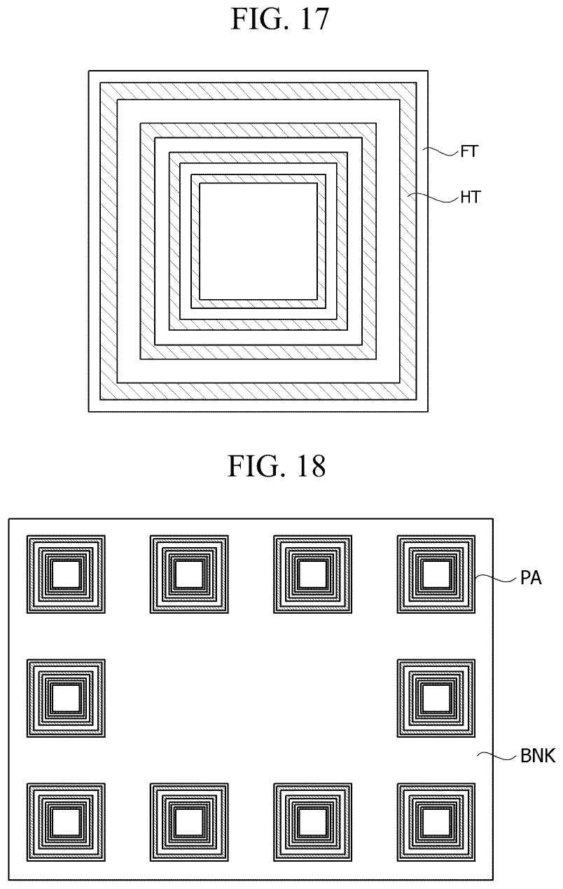

FIG. 16 is an enlarged cross-sectional view of region 1, FIG. 17 is a view illustrating a masking pattern forming the test pad of FIG. 16, and FIG. 18 is an enlarged plan view of region 1.

As shown in FIG. 16, a method of manufacturing the display device according to one embodiment of the present specification is as follows.

A bank BNK is formed, and a first layer L1, which is a connection line SL connected to a test pad 10, may be disposed on an upper surface of the bank BNK. In one embodiment, the first layer L1 in FIG. 16 may be the M4 layer in FIG. 15. A second layer L2 may be the indium layer F4 in FIG. 15.

A photoresist layer PR (F5 in FIG. 15) is formed on the first layer L1, and a pattern is formed in the photoresist layer PR through an exposure process. The second layer L2 may then be formed or deposited on the photoresist layer PR, which includes a pattern area PA. During the process of forming or depositing the second layer L2, ESD may occur when charges accumulated on a display panel 100 inside a process chamber are discharged as the process chamber is opened, and the test pad 10 may be affected by the ESD occurring in this manner.

To adjust a taper angle of the pattern area PA, as shown in FIG. 17, a pattern may be formed in the photoresist layer PR by exposing the photoresist layer PR to light through a mask that includes full-tone (FT) slits and half-tone (HT) slits.

The pattern area PA formed in this manner may have a positive taper cross-section, as shown in FIG. 16. For example, the photoresist layer PR including the pattern area PA may have a positive taper sidewall. Accordingly, the second layer L2 may be formed or deposited in such a way that a connection thereof is maintained even in the pattern area PA, and since the entire second layer L2 is connected through the pattern area PA, the first layer L1 and the second layer L2 be in contact with each other through the pattern area PA, thereby forming an equipotential state.

Even when the pattern area PA has a positive taper cross-section, when a depth of the pattern area PA is significant, the connection of the second layer L2 may be interrupted during the formation or deposition process of the second layer L2. In the embodiment of the present specification, by forming the bank BNK and disposing the first layer L1 on the upper surface of the formed bank BNK, the depth of the pattern area PA is reduced, which allows the first layer L1 and the second layer L2 to be in contact with each other at a relatively higher point, thereby maintaining the connection of the second layer L2 in the pattern area PA. In one embodiment, the bank BNK may be formed on a base layer BL.

In one embodiment of the present specification, the mask may include a second slit that is formed by reducing a first slit at a certain ratio and located inside the first slit, or a second slit having a different size from the first slit. The first slit may be an FT slit, and the second slit may be an HT slit, but the present specification is not limited thereto. For example, sizes of the FT slit and the HT slit may be different from each other. For example, the FT slit may increase in size from the inside to the outside of the mask, but the present specification is not limited thereto. The FT slit may increase in size by approximately 0.2 μm as it extends from the inside to the outside of the mask, but the present specification is not limited thereto. For example, the HT slit may decrease in size from the inside to the outside of the mask, but the present specification is not limited thereto. The HT slit may decrease in size by approximately 0.3 μm as it extends from the inside to the outside of the mask, but the present specification is not limited thereto. For example, the mask may be a mask having a repeating pattern of FT slits and HT slits, as shown in FIG. 17, but the present specification is not limited thereto. For example, the mask may have a rectangular shape, but the present specification is not limited thereto. Other types of masks that can form a pattern in the photoresist layer PR such that the pattern area PA has a positive taper cross-section may also be used.

In one embodiment, a position at which the pattern area PA is formed on the bank BNK may be as shown in FIG. 18, and through the pattern area PA formed in this manner, the first layer L1 and the second layer L2 may be in contact with each other, thereby forming an equipotential state.

In the test pad 10, the first layer L1 and the second layer L2 are in contact with each other to form an equipotential state, whereas in the shorting bar 20, the first layer L1 and the second layer L2 have a potential difference, thereby allowing ESD to be induced to the shorting bar 20 rather than to the test pad 10. Accordingly, ESD occurring in the test pad 10 may be mitigated. For example, the potential difference of the shorting bar 20 may be set to be greater than a potential difference of the display area AA, and ESD may be induced to the shorting bar 20.

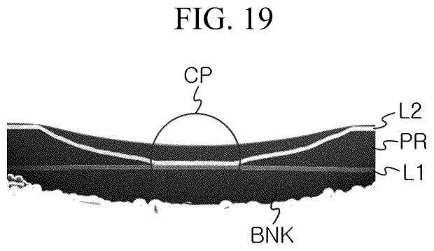

FIG. 19 is a view illustrating an implementation of the test pad according to an example embodiment of the present specification.

As described above, it can be confirmed that the first layer L1 disposed on the bank BNK and the second layer L2 formed or deposited on the photoresist layer PR including the pattern area PA are in contact with each other at a bottom point CP of the pattern area.

In one embodiment of the present specification, the first layer L1 may be a metal layer, and the second layer L2 may be an indium layer. The test pad 10 may form an equipotential state as the metal layer and the indium layer are in contact with each other. Accordingly, ESD occurring in the test pad of the display panel using micro LEDs (or micro light-emitting elements) can be mitigated.

In the display device according to one embodiment of the present specification, the first layer, which is a connection line in the test pad, is disposed on the upper surface of the bank, and the pattern area formed by exposure of the photoresist layer has a positive taper cross-section, and thus, the second layer, which is formed or deposited on the photoresist layer, can maintain a connection thereof even in the pattern area. Based on this, the first layer and the second layer may be in contact with each other through the pattern area, thereby forming an equipotential state between the two layers. Accordingly, ESD occurring during the formation or deposition of the second layer in the test pad of the display device using micro LEDs can be mitigated.

The display device and the method of manufacturing the same according to one or more embodiments of the present specification may be described as follows.

A display device according to one or more embodiments of the present specification may include a substrate including a display area and a non-display area around the display area, a signal line located in the display area, a test pad located in the non-display area, and a connection line located in the non-display area and configured to electrically connect the test pad and the signal line. The test pad may include a bank, a first layer, which is the connection line, disposed on the bank, a photoresist layer disposed on the first layer and including a pattern area, and a second layer disposed on the photoresist layer. The pattern area may have a positive taper cross-section, and the first layer and the second layer may be in contact with each other in the pattern area.

According to one or more embodiments of the present specification, the first layer and the pattern area may be in contact with each other on the bank.

According to one or more embodiments of the present specification, the second layer may be entirely connected through the pattern area.

According to one or more embodiments of the present specification, the pattern area may be formed through exposure using a mask that includes a full-tone slit and a half-tone slit.

According to one or more embodiments of the present specification, in the mask, sizes of the full-tone slit and the half-tone slit may be different from each other, and the full-tone slit and the half-tone slit may be repeatedly disposed.

According to one or more embodiments of the present specification, the first layer may be in contact with the second layer through a portion at which the first layer and the pattern area are in contact with each other, and thus may be equipotential with the second layer.

According to one or more embodiments of the present specification, based on the first layer and the second layer being equipotential, static electricity may be discharged to a shorting bar.

According to one or more embodiments of the present specification, the first layer may be a metal layer, and the second layer may be an indium layer.

According to one or more embodiments of the present specification, the display area may include a micro light-emitting element, and a signal for driving the micro light-emitting element may be tested through the test pad.

According to one or more embodiments of the present specification, the micro light-emitting element may have a vertical structure.

A method of manufacturing a display panel according to one or more embodiments of the present specification may include forming a bank on a substrate, forming a first layer, which is a connection line connected to a test pad, on the bank, forming a photoresist layer on the first layer, forming a pattern area in the photoresist layer through exposure, and forming a second layer on the photoresist layer in which the pattern area is formed. The pattern area may have a positive taper cross-section, and the first layer and the second layer may be in contact with each other in the pattern area.

According to one or more embodiments of the present specification, the first layer and the pattern area may be in contact with each other on the bank.

According to one or more embodiments of the present specification, the second layer may be entirely connected through the pattern area.

According to one or more embodiments of the present specification, the forming of the pattern area may include irradiating light onto the photoresist layer through a mask including a full-tone slit and a half-tone slit.

According to one or more embodiments of the present specification, in the mask, sizes of the full-tone slit and the half-tone slit may be different from each other, and the full-tone slit and the half-tone slit may be repeatedly disposed.

According to one or more embodiments of the present specification, the first layer may be in contact with the second layer through a portion at which the first layer and the pattern area are in contact with each other, and thus may be equipotential with the second layer.

According to one or more embodiments of the present specification, the display device may further include a shorting bar located near the test pad, and based on the first layer and the second layer being equipotential, static electricity may be discharged to the shorting bar.

According to one or more embodiments of the present specification, the first layer may be a metal layer, and the second layer may be an indium layer.

According to one or more embodiments of the present specification, a display area on the substrate may include a micro light-emitting element, and a signal for driving the micro light-emitting element may be tested through the test pad.

According to one or more embodiments of the present specification, the micro light-emitting element may have a vertical structure.

According to one or more embodiments of the present specification, a first layer and a second layer of a connection line can be brought into contact with each other through a pattern area, thereby making the two layers equipotential. Accordingly, ESD occurring in a test pad of a display device using micro LEDs can be reduced or mitigated. As a result, a manufacturing process of a display device can be optimized, thereby reducing greenhouse gas emissions in terms of the production aspect of the display device.

The effects of the present specification are not limited to the effects mentioned above, and other effects not mentioned can be clearly understood by those skilled in the art to which the technical idea of the present specification pertains from the following description.

While various example embodiments of the present disclosure have been described in detail above with reference to the accompanying drawings, the present disclosure is not necessarily limited to these embodiments, and various changes and modifications may be made without departing from the technical concept or spirit of the present disclosure. Accordingly, the example embodiments disclosed herein are intended to illustrate and not to limit the technical ideas of the present disclosure, and the scope of the technical ideas of the present disclosure is not limited by these embodiments. Accordingly, the above-described embodiments should be understood to be examples and not limiting in any aspect.

What is claimed is:

1. A display device, comprising:
a substrate including a display area and a non-display area around the display area;
a signal line located in the display area;
a test pad located in the non-display area; and
a connection line located in the non-display area and configured to electrically connect the test pad and the signal line,
wherein the test pad includes:
a bank;
a first layer, which is the connection line, disposed on the bank;
a photoresist layer disposed on the first layer and including a pattern area; and
a second layer disposed on the photoresist layer,
wherein the pattern area has a positive taper cross-section, and
wherein the first layer and the second layer are in contact with each other in the pattern area.

2. The display device of claim 1, wherein the first layer and the pattern area are in contact with each other on the bank.

3. The display device of claim 1, wherein the second layer is entirely connected through the pattern area.

4. The display device of claim 1, wherein the first layer is in contact with the second layer through a portion at which the first layer and the pattern area are in contact with each other, the first layer being equipotential with the second layer.

5. The display device of claim 4, wherein, based on the first layer and the second layer being equipotential, static electricity is discharged to a shorting bar.

6. The display device of claim 5, wherein the shorting bar includes:
a bank;
a first layer disposed on the bank;
a photoresist layer disposed on the first layer; and
a second layer disposed on the photoresist layer,
wherein the second layer of the shorting bar and the second layer of the test pad are continuous, and
wherein the first layer of the shorting bar and the second layer of the shorting bar have a potential difference.

7. The display device of claim 6, wherein the display area includes:
a bank;
a first layer disposed on the bank;
a photoresist layer disposed on the first layer; and
a second layer disposed on the photoresist layer,
wherein the second layer of the display area is continuous with the second layer of the shorting bar and the second layer of the test pad, and
wherein a potential difference between the first layer of the display area and the second layer of the display area is smaller than the potential difference of the shorting bar.

8. The display device of claim 1, wherein:
the first layer is a metal layer, and
the second layer is an indium-based layer.

9. The display device of claim 1, wherein:
the display area includes a micro light-emitting element, and
a signal for driving the micro light-emitting element is tested through the test pad.

10. The display device of claim 9, wherein the micro light-emitting element has a vertical structure.

11. A method of manufacturing a display device, comprising:
forming a bank on a substrate;
forming a first layer, which is a connection line connected to a test pad, on the bank;
forming a photoresist layer on the first layer;
forming a pattern area in the photoresist layer through exposure; and
forming a second layer on the photoresist layer in which the pattern area is formed,
wherein the pattern area has a positive taper cross-section, and
wherein the first layer and the second layer are in contact with each other in the pattern area.

12. The method of claim 11, wherein the first layer and the pattern area are in contact with each other on the bank.

13. The method of claim 11, wherein the second layer is entirely connected through the pattern area.

14. The method of claim 11, wherein the forming of the pattern area includes irradiating light onto the photoresist layer through a mask including a full-tone slit and a half-tone slit.

15. The method of claim 14, wherein, in the mask:
sizes of the full-tone slit and the half-tone slit are different from each other, and
the full-tone slit and the half-tone slit are repeatedly disposed.

16. The method of claim 15, wherein, in the mask, the full-tone slit that is formed by reducing the half-tone slit at a certain ratio is located inside the half-tone slit.

17. The method of claim 15, wherein, in the mask:
the full-tone slit increases in size from an inside to an outside of the mask, and
the half-tone slit decreases in size from the inside to the outside of the mask.

18. The method of claim 11, wherein the first layer is in contact with the second layer through a portion at which the first layer and the pattern area are in contact with each other, is the first layer being equipotential with the second layer.

19. The method of claim 18, wherein:
the display device further includes a shorting bar located near the test pad, and
based on the first layer and the second layer being equipotential, static electricity is discharged to the shorting bar.

20. The method of claim 11, wherein:
the first layer is a metal layer, and
the second layer is an indium-based layer.
